(19) United States
(12) Patent Application Publication
(10) Pub. No.: US 2025/0279361 A1
(43) Pub. Date: Sep. 4, 2025

(54) SEMICONDUCTOR MEMORY DEVICE

(71) Applicant: Kioxia Corporation, Tokyo (JP)

(72) Inventor: Naoki HASHIMOTO, Yokkaichi (JP)

(73) Assignee: Kioxia Corporation, Tokyo (JP)

(21) Appl. No.: 18/823,291

(22) Filed: Sep. 3, 2024

(30) Foreign Application Priority Data
Mar. 4, 2024 (JP) 2024-032187

(51) Int. Cl. H01L 23/528; G11C 16/04; H10B 43/10; H10B 43/35

(52) U.S. Cl. CPC H01L 23/5283; G11C 16/0483; H10B 43/10; H10B 43/35

(57) ABSTRACT

According to one embodiment, a semiconductor memory device includes: a substrate provided with a plane formed by first and second directions, and including first and second regions aligned in the first direction, the second region including third and fourth regions aligned in the second direction; interconnect layers arranged with the substrate in a third direction, being spaced from one another in the third direction, and each including a bridge portion and a terrace portion; a contact extending in the third direction; a conductor isolated from the interconnect layers excluding a first interconnect layer, and including, a first portion contacting the terrace portion of the first interconnect layer in the fourth region, a second portion contacting the contact in the third region, and a third portion coupling the first and second portions; and a memory pillar extending in the third direction in the first region.

### CROSS-REFERENCE TO RELATED APPLICATION

This application is based upon and claims the benefit of priority from Japanese Patent Application No. 2024-032187, filed Mar. 4, 2024, the entire contents of which are incorporated herein by reference.

### FIELD

Embodiments described herein relate generally to a semiconductor memory device.

### BACKGROUND

A NAND flash memory is known as a semiconductor memory device capable of storing data in a non-volatile manner. For a NAND flash memory, a three-dimensional memory structure may be adopted for high integration and large capacity.

### BRIEF DESCRIPTION OF THE DRAWINGS

FIG. 1 is a block diagram showing an example of a configuration of a memory system according to an embodiment.

FIG. 2 is a circuit diagram showing an example of a circuit configuration of a memory cell array included in a semiconductor memory device according to the embodiment.

FIG. 3 is a plan view showing an example of a planar layout of the memory cell array included in the semiconductor memory device according to the embodiment.

FIG. 4 is a plan view showing an example of a planar layout of a memory region of the memory cell array included in the semiconductor memory device according to the embodiment.

FIG. 5 is a cross-sectional diagram taken along line V-V of FIG. 4, showing an example of a cross-sectional structure of the memory region of the memory cell array included in the semiconductor memory device according to the embodiment.

FIG. 6 is a cross-sectional diagram taken along line VI-VI of FIG. 5, showing an example of a cross-sectional structure of a memory pillar in the semiconductor memory device according to the embodiment.

FIG. 7 is a plan view showing an example of a planar layout in a hookup region of the memory cell array included in the semiconductor memory device according to the embodiment.

FIG. 8 is a cross-sectional diagram taken along line VIII-VIII of FIG. 7, showing an example of a cross-sectional structure in the hookup region of the memory cell array included in the semiconductor memory device according to the embodiment.

FIG. 9 is a cross-sectional diagram taken along line IX-IX of FIG. 7, showing an example of a cross-sectional structure in the hookup region of the memory cell array included in the semiconductor memory device according to the embodiment.

FIG. 10 is a cross-sectional diagram taken along line X-X of FIG. 8, showing an example of a cross-sectional structure in the hookup region of the memory cell array included in the semiconductor memory device according to the embodiment.

FIG. 11 is a cross-sectional diagram taken along line XI-XI of FIG. 8, showing an example of a cross-sectional structure in the hookup region of the memory cell array included in the semiconductor memory device according to the embodiment.

FIG. 12 is a plan view taken along line XII-XII of FIG. 8, showing an example of a planar layout in the hookup region of the memory cell array included in the semiconductor memory device according to the embodiment.

FIG. 13 is a cross-sectional diagram taken along line XIII-XIII of FIG. 8, showing an example of a cross-sectional structure in the hookup region of the memory cell array included in the semiconductor memory device according to the embodiment.

FIG. 14 is a plan view taken along line XIV-XIV of FIG. 8, showing an example of a planar layout in the hookup region of the memory cell array included in the semiconductor memory device according to the embodiment.

FIG. 15 is a flowchart showing an example of manufacturing steps of the semiconductor memory device according to the embodiment.

FIG. 16 is a cross-sectional diagram showing an example of a cross-sectional structure of the semiconductor memory device in the course of manufacturing according to the embodiment.

FIG. 17 is a cross-sectional diagram showing an example of a cross-sectional structure of the semiconductor memory device in the course of manufacturing according to the embodiment.

FIG. 18 is a cross-sectional diagram showing an example of a cross-sectional structure of the semiconductor memory device in the course of manufacturing according to the embodiment.

FIG. 19 is a cross-sectional diagram showing an example of a cross-sectional structure of the semiconductor memory device in the course of manufacturing according to the embodiment.

FIG. 20 is a cross-sectional diagram showing an example of a cross-sectional structure of the semiconductor memory device in the course of manufacturing according to the embodiment.

FIG. 21 is a cross-sectional diagram showing an example of a cross-sectional structure of the semiconductor memory device in the course of manufacturing according to the embodiment.

FIG. 22 is a cross-sectional diagram showing an example of a cross-sectional structure of the semiconductor memory device in the course of manufacturing according to the embodiment.

FIG. 23 is a cross-sectional diagram showing an example of a cross-sectional structure of the semiconductor memory device in the course of manufacturing according to the embodiment.

FIG. 24 is a cross-sectional diagram showing an example of a cross-sectional structure of the semiconductor memory device in the course of manufacturing according to the embodiment.

FIG. 25 is a plan view showing an example of a planar layout of the semiconductor memory device in the course of manufacturing according to the embodiment.

FIG. 26 is a plan view showing an example of a planar layout of the semiconductor memory device in the course of manufacturing according to the embodiment.

FIG. 27 is a cross-sectional diagram showing an example of a cross-sectional structure of the semiconductor memory device in the course of manufacturing according to the embodiment.

FIG. 28 is a cross-sectional diagram showing an example of a cross-sectional structure of the semiconductor memory device in the course of manufacturing according to the embodiment.

### DETAILED DESCRIPTION

In general, according to one embodiment, a semiconductor memory device includes: a substrate provided with a plane formed by a first direction and a second direction intersecting each other, the substrate including a first region and a second region aligned in the first direction, the second region including a third region and a fourth region aligned in the second direction; a plurality of interconnect layers arranged with the substrate in a third direction and including a first interconnect layer, the third direction intersecting each of the first direction and the second direction, the plurality of interconnect layers being spaced from one another in the third direction and each including a bridge portion extending in the first direction in the third region and a terrace portion provided so as not to overlap, in the third direction, an upper interconnect layer in the fourth region; a first contact extending in the third direction; a first conductor provided so as to be distanced from the plurality of interconnect layers excluding the first interconnect layer, the first conductor including a first portion contacting the terrace portion of the first interconnect layer in the fourth region, a second portion contacting one end of the first contact in the third region, and a third portion coupling the first portion and the second portion; and a first memory pillar extending in the third direction in the first region, a portion of the first memory pillar intersecting the first interconnect layer functioning as a first memory cell.

Hereinafter, embodiments will be described with reference to the accompanying drawings. The drawings are schematic, and the dimensions and ratios in the drawings are not always the same as the actual ones. In the description that follows, structural components having substantially the same function and configuration will be denoted by the same reference symbol. To particularly distinguish a plurality of components with a similar configuration, such components may be referred to by an identical reference numeral with different characters or numbers added at the end.

In the description that follows, a first element being “coupled to” a second element encompasses a case where the first element is indirectly connected to the second element via an intervening element that is constantly or selectively conductive, or directly connected to the second element without an intervening element.

### 1. Configuration

### 1.1 Memory System

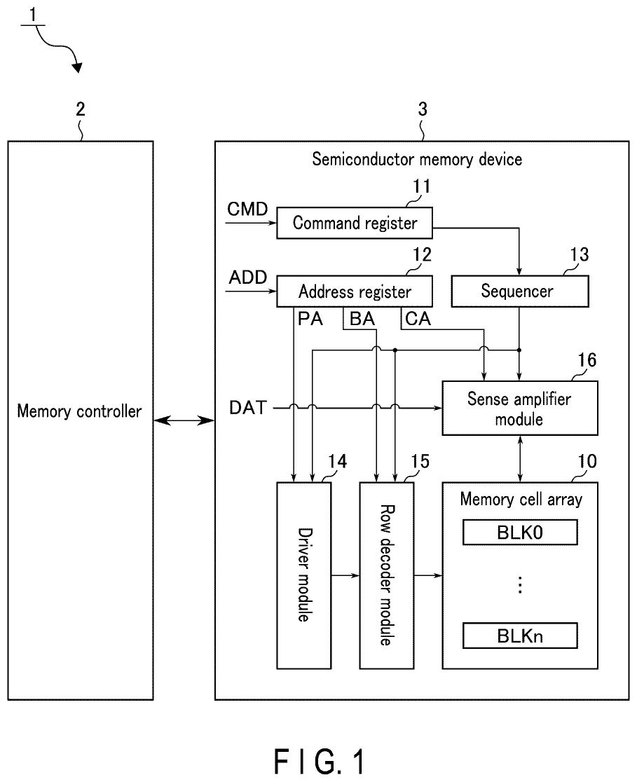

FIG. 1 is a block diagram showing an example of a configuration of a memory system, which is a storage device configured to be coupled to an external host device (not illustrated), according to an embodiment. Examples of such a memory system include a memory card such as an SD™ card, a universal flash storage (UFS), a solid-state drive (SSD), etc. The memory system 1 includes a memory controller 2 and a semiconductor memory device 3.

The memory controller 2 is configured of an integrated circuit such as a system on a chip (SoC). The memory controller 2 controls the semiconductor memory device 3 based on a request from an external host device. Specifically, the memory controller 2 writes data for which a write request has been made from the external host device into the semiconductor memory device 3. Also, the memory controller 2 reads the data for which the read request has been made from the external host device from the semiconductor memory device 3 and outputs the read data to the external host device.

The semiconductor memory device 3 is, for example, a NAND flash memory, capable of storing data in a non-volatile manner.

Communications between the memory controller 2 and the semiconductor memory device 3 are compliant with a single data rate (SDR) interface, a toggle double data rate (DDR) interface, or an Open NAND Flash Interface (ONFI).

### 1.2 Semiconductor Memory Device

Hereinafter, an internal configuration of a semiconductor memory device according to the embodiment will be described with reference to the block diagram shown in FIG. 1. The semiconductor memory device 3 includes, for example, a memory cell array 10, a command register 11, an address register 12, a sequencer 13, a driver module 14, a row decoder module 15, and a sense amplifier module 16.

The memory cell array 10 is configured of a set of memory cell transistors and structural components coupled to the memory cell transistors. The memory cell array 10 includes a plurality of blocks BLK0 to BLKn (where n is an integer not less than 1). Each block BLK includes a set of memory cell transistors capable of storing data in a non-volatile manner. Each block BLK is used as, for example, a unit of data erasure in the case of erasing data stored in the memory cell transistors. In the memory cell array 10, a plurality of bit lines and a plurality of word lines are provided. Each memory cell is associated with, for example, a combination of a single bit line and a single word line. A detailed configuration of the memory cell array 10 will be described later.

The command register 11 stores a command CMD received by the semiconductor memory device 3 from the memory controller 2. The command CMD includes an instruction to cause the sequencer 13 to perform, for example, a read operation, a write operation, an erase operation, etc.

The address register 12 stores address information ADD received by the semiconductor memory device 3 from the memory controller 2. The address information ADD includes, for example, a block address BA, a page address PA, and a column address CA. The block address BA, the page address PA, and the column address CA are used to respectively select, for example, a block BLK, a word line, and a bit line.

The sequencer 13 controls the entire operation of the semiconductor memory device 3. For example, the sequencer 13 controls the driver module 14, the row decoder module 15, and the sense amplifier module 16, etc., based on the command CMD stored in the command register 11, to perform a read operation, a write operation, an erase operation, etc.

The driver module 14 generates voltages with different magnitudes to be used in a read operation, a write operation, an erase operation, etc. Based on, for example, the page address PA stored in the address register 12, the driver module 14 applies the generated voltage to a signal line corresponding to a selected word line.

Based on the block address BA stored in the address register 12, the row decoder module 15 selects a single corresponding block BLK in the memory cell array 10. Thereafter, the row decoder module 15 transfers a voltage of the signal line corresponding to the word line selected based on the page address PA stored in the address register 12 and applied by, for example, the driver module 14 to the selected word line in the selected block BLK.

In a write operation, the sense amplifier module 16 applies, to each bit line BL, a desired voltage determined in accordance with write data DAT received from the memory controller 2. In a read operation, the sense amplifier module 16 determines data stored in a memory cell based on the magnitude of the voltage of the bit line. The sense amplifier module 16 transfers the result of the determination to the memory controller 2 as read data DAT.

### 1.3 Circuit Configuration of Memory Cell Array

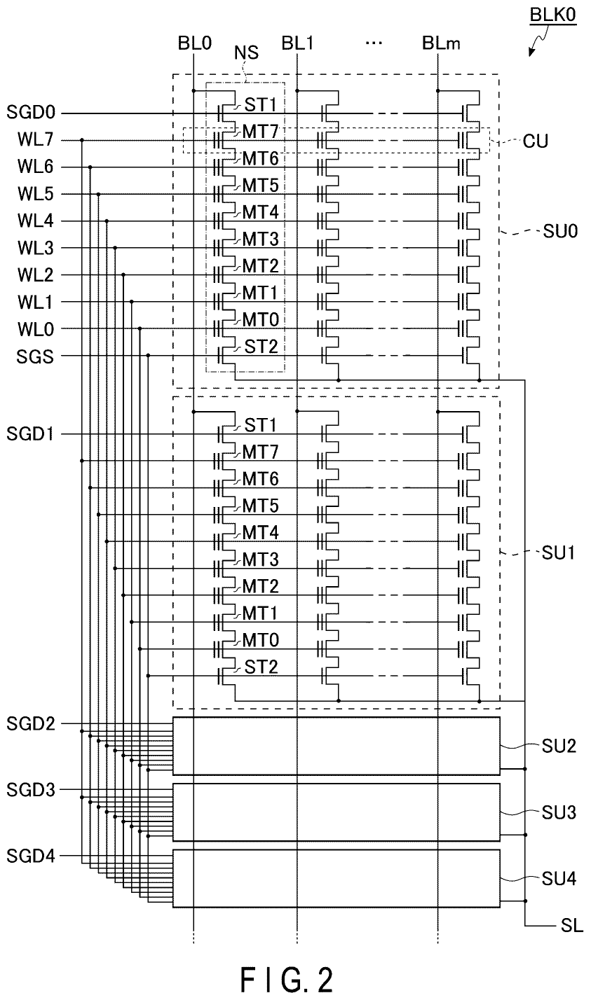

FIG. 2 is a circuit diagram showing an example of a circuit configuration of a memory cell array included in the semiconductor memory device according to the first embodiment. In FIG. 2, a block BLK0 of a plurality of blocks BLK included in the memory cell array 10 is shown. The block BLK0 includes, for example, five string units SU0 to SU4. Each string unit SU includes a set of NAND strings NS that are respectively associated with bit lines BL0 to BLm (where m is an integer not less than 1). Each NAND string NS includes, for example, eight memory cell transistors MT0 to MT7 and select transistors ST1 and ST2. Each memory cell transistor MT includes a control gate and a charge storage film, and stores data in a non-volatile manner based on an amount of charge in the charge storage film. Each of the select transistors ST1 and ST2 is used to select a string unit SU in various operations.

In each NAND string NS, the memory cell transistors MT0 to MT7 are coupled in series in this order. A drain of the select transistor ST1 is coupled to a corresponding bit line BL, and a source of the select transistor ST1 is coupled to a drain of the memory cell transistor MT7. A drain of the select transistor ST2 is coupled to a source of the memory cell transistor MT0, and a source of the select transistor ST2 is coupled to a source line SL.

Control gates of sets of memory cell transistors MT0 to MT7 in the same block BLK are respectively coupled in common to the word lines WLO to WL7. Gates of the select transistors ST1 in the string units SU0 to SU4 are respectively coupled in common to the select gate lines SGD0 to SGD4. Gates of the select transistors ST2 in the same block BLK are coupled to a select gate line SGS.

The bit lines BL0 to BLm are assigned different column addresses CA. Each bit line BL is shared among a plurality of NAND strings NS that are assigned the same column address CA among the plurality of blocks BLK. A set of word lines WL0 to WL7 is provided for each block BLK. The source line SL is shared among, for example, a plurality of blocks BLK.

A set of memory cell transistors MT coupled to a common word line WL in a single string unit SU is referred to as, for example, a cell unit CU. For example, the storage capacity of a cell unit CU including memory cell transistors MT, which individually store 1-bit data, is defined as “1-page data”. A cell unit CU may have a storage capacity of 2 or more pages of data, according to the number of bits of data stored in the memory cell transistor MT.

The circuit configuration of the memory cell array 10 included in the semiconductor memory device 3 according to the embodiment is not limited to the above-described one. For example, the number of string units SU included in each block BLK may be set to any number. Also, the numbers of memory cell transistors MT and select transistors ST1 and ST2 included in each NAND string NS may be designed to be any number.

### 1.4 Structure of Memory Cell Array

Hereinafter, an example structure of a memory cell array included in the semiconductor memory device according to the embodiment will be described. In the drawings that will be referred to below, a three-dimensional orthogonal coordinate system will be used. An “X direction” corresponds to a direction in which the word lines WL extend. A “Y direction” corresponds to a direction in which the bit lines BL extend. A “Z direction” corresponds to a direction vertical to the surface of a semiconductor substrate 20 used for forming the semiconductor memory device 3. A side of the Z direction on which semiconductor circuitry is formed as viewed from the semiconductor substrate 20 is defined as an “upper direction”, and a direction opposite to the upper direction is defined as a “lower direction”. In the plan views, hatching is applied, as appropriate, for improved visibility. The hatching applied in the plan views does not necessarily relate to the material or characteristics of the hatched components. In the cross-sectional views, some of the components are suitably omitted, for improved visibility.

In the description that follows, a “region” may be regarded as a configuration included in a semiconductor substrate. For example, if the semiconductor substrate 20 is defined as including a first region and a second region, the first region and the second region are associated with different regions above the semiconductor substrate 20.

### 1.4.1 Overview of Planar Layout

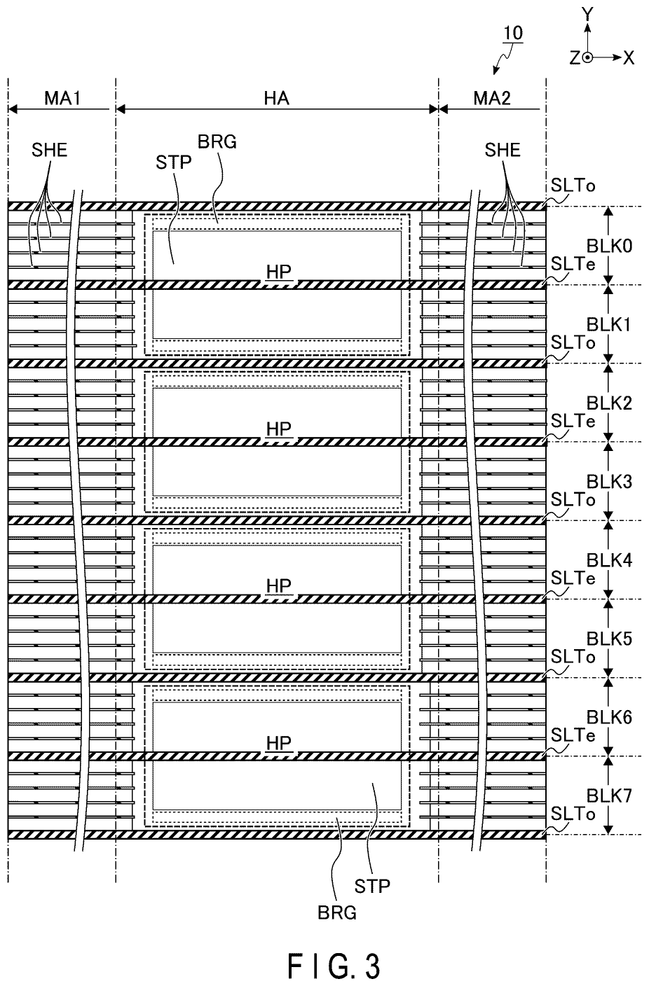

FIG. 3 is a plan view showing an example of a planar layout of the memory cell array included in the semiconductor memory device according to the embodiment. FIG. 3 shows a region corresponding to eight blocks BLK0 to BLK7. The sequential numbers at the end for distinguishing between the blocks BLK are assigned in increasing order from the top as viewed in the drawing. In the memory cell array 10, the layout shown in FIG. 3, for example, is repeatedly arranged in the Y direction.

As shown in FIG. 3, the memory cell array 10 includes a plurality of members SLT and a plurality of members SHE. A planar layout of the memory cell array 10 is divided into, for example, memory regions MA1 and MA2 and a hookup region HA in the X direction. The hookup region HA is arranged between the memory regions MA1 and MA2.

Each of the memory regions MA1 and MA2 is a region including a plurality of NAND strings NS. The hookup region HA is used for coupling between the row decoder module 15 and stacked interconnects configured of a plurality of interconnect layers (e.g., the word lines WL0 to WL7 and the select gate lines SGD and SGS) stacked in the Z direction so as to be spaced from one another.

The members SLT each extend in the X direction, and are aligned in the Y direction. Each member SLT crosses, in a boundary region between adjacent blocks BLK, the memory regions MA1 and MA2 and the hookup region HA in the X direction. In other words, each of the regions partitioned by the members SLT corresponds to a single block BLK in the memory cell array 10. Each member SLT has, for example, a structure in which an insulator and a plate-shaped contact is embedded. Each member SLT divides sets of stacked interconnects that are adjacent to one another with the member SLT interposed therebetween.

As shown in FIG. 3, in the present embodiment, of a plurality of members SLT aligned in the Y direction, those in the odd-numbered rows will be referred to as “SLTo”, and those in the even-numbered rows will be referred to as “SLTe”. In the memory cell array 10, sets of members SLTo and SLTe are aligned in the Y direction.

The members SHE are arranged in each of the memory regions MA1 and MA2. The members SHE in the memory region MA1 are each provided so as to cross the memory region MA1 in the X direction, and are aligned in the Y direction. The members SHE in the memory region MA2 are each provided so as to cross the memory region MA2 in the X direction, and are aligned in the Y direction. Right end portions of the members SHE provided in the memory region MA1 and left end portions of the members SHE provided in the memory region MA2, as viewed in the drawing, are included in the hookup region HA. For example, four members SHE are arranged in each of the memory regions MA1 and MA2 between two members SLT adjacent to each other in the Y direction. A combination of each of the regions partitioned by the members SLT and SHE of the memory region MA1 and each of the regions partitioned by the members SLT and SHE of the memory region MA2 corresponds to a single string unit SU in the memory cell array 10. Each member SHE has, for example, a structure in which an insulator is embedded. Each member SHE divides select gate lines SGD that are adjacent to each other with the member SHE interposed therebetween.

The hookup region HA includes a plurality of hookup portions HP aligned in the Y direction. The hookup portion HP is arranged in every two blocks BLK. In other words, in the hookup region HA, each hookup portion HP is arranged in a region interposed by two members SLTo sandwiching two adjacent blocks BLK and a member SLTe.

Each hookup portion HP includes a staircase region STP and two bridge regions BRG. The staircase region STP is a region including a staircase structure of stacked interconnects. The two bridge regions BRG are aligned in the Y direction so as to sandwich the staircase region STP.

In the hookup portion HP, the staircase region STP is arranged across a single member SLTe provided between two adjacent blocks BLK. The member SLTe intersecting the staircase region STP divides the staircase structure of the stacked interconnects of two adjacent blocks BLK that share the staircase region STP into two portions corresponding to the blocks BLK.

In each hookup portion HP, each of the two bridge regions BRG is provided so as to be adjacent to a corresponding one of two members SLTo provided so as to sandwich the staircase region STP. In each block BLK, the stacked interconnects on the side of the memory region MA1 and the stacked interconnects on the side of the memory region MA2 are, except for one or more upper interconnect layers, electrically coupled via the bridge region BRG so as to bypass the staircase region STP. Of the one or more upper interconnect layers (e. g., the interconnect layer corresponding to the word line WL7), those on the side of the memory region MA1 and those on the side of the memory region MA2 are coupled via an unillustrated interconnect provided above the interconnect layers.

The planar layout of the memory cell array 10 included in the semiconductor memory device 3 according to the embodiment is not limited to the above-described one. For example, the number of members SHE arranged between adjacent members SLT may be designed to be a given number. The number of string units SU formed between adjacent members SLT may be changed based on the number of members SHE arranged between adjacent members SLT.

### 1.4.2 Memory Region

### 1.4.2.1 Planar Layout

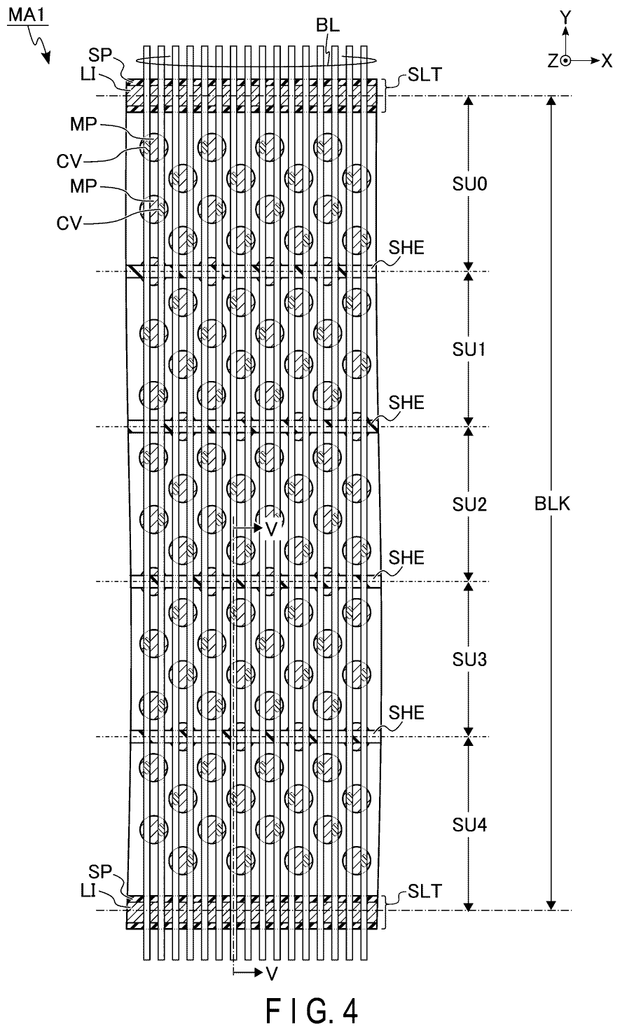

FIG. 4 is a plan view showing an example of a planar layout of a memory region of the memory cell array included in the semiconductor memory device according to the embodiment. In FIG. 4, a structure of a single block BLK in the memory region MA1 is shown as a representative; however, the memory region MA2 has a structure similar to the memory region MA1. As shown in FIG. 4, the memory cell array 10 includes, in the memory region MA, a plurality of memory pillars MP, a plurality of contacts CV, and a plurality of bit lines BL. Each member SLT includes a contact LI and a spacer SP.

Each of the memory pillars MP functions as, for example, a single NAND string NS. The memory pillars MP are in, for example, a 24-column staggered arrangement in a region between two adjacent members SLT. In the example shown in FIG. 4, four members SHE respectively overlap the memory pillars MP in the fifth, tenth, fifteenth, and twentieth columns, counted from the top as viewed in the drawing.

The bit lines BL each extend in the Y direction, and are aligned in the X direction. Each bit line BL is arranged to overlap at least one memory pillar MP in each string unit SU. In the example shown in FIG. 4, two bit lines BL are arranged to overlap a single memory pillar MP. If each memory pillar MP is overlapped by a plurality of bit lines BL, electrical coupling is provided between one of the bit lines BL and the memory pillar MP via a corresponding contact CV. If each memory pillar MP is overlapped by only one bit line BL, electrical coupling is provided between the bit line BL and the memory pillar MP via a corresponding contact CV.

A contact CV between a memory pillar MP that contacts a member SHE and a corresponding bit line BL, for example, is omitted. In other words, a contact CV between a memory pillar MP that is in contact with two different select gate lines SGD and a bit line BL is omitted. The number and arrangement of the memory pillars MP, the members SHE, etc. in adjacent members SLT are not limited to those in the configuration shown in FIG. 4, and may be suitably varied. For example, the number of bit lines BL overlapping each memory pillar MP may be designed to be any number.

The contact LI is a conductor extending in an XZ plane. The spacer SP is an insulator provided on a side surface of the contact LI. In other words, the spacer SP is provided so as to be in contact with the contact LI so as to sandwich the contact LI in the Y direction.

### 1.4.2.2 Cross-Sectional Structure

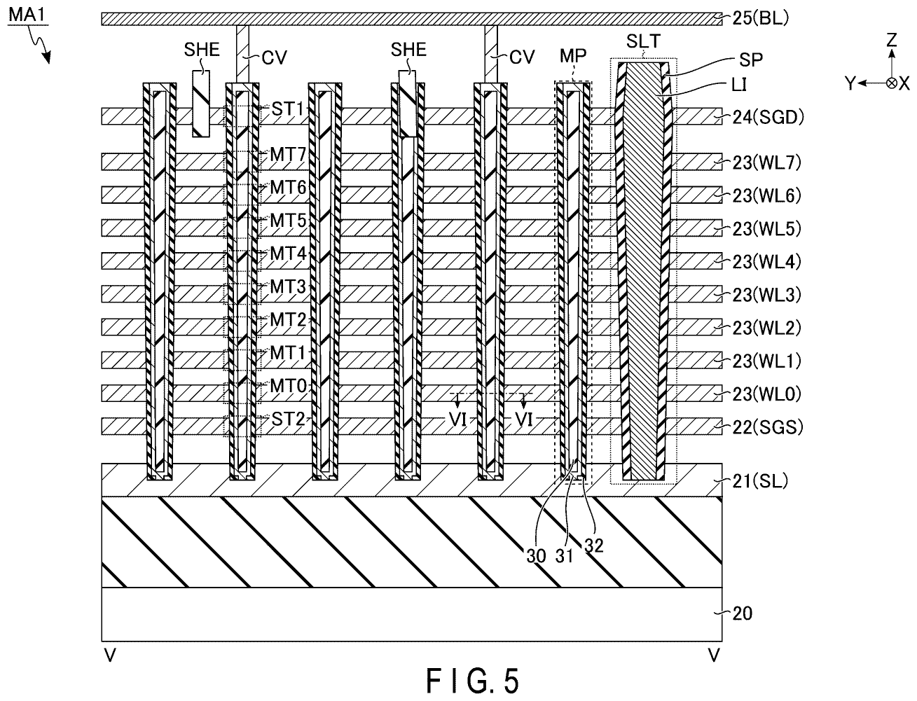

FIG. 5 is a cross-sectional diagram taken along line V-V of FIG. 4, showing an example of a cross-sectional structure of the memory region of the memory cell array included in the semiconductor memory device according to the embodiment. As shown in FIG. 5, the memory cell array 10 further includes interconnect layers 21 to 25.

An interconnect layer 21 is provided above the semiconductor substrate 20, with an insulating layer interposed therebetween. Although illustration is omitted, circuits corresponding to, for example, the row decoder module 15 and the sense amplifier module 16 are provided in the insulating layer between the semiconductor substrate 20 and the interconnect layer 21. Each interconnect layer 21 is formed in, for example, a plate-like shape extending along the XY plane. The interconnect layer 21 is used as a source line SL. The interconnect layer 21 contains, for example, phosphorus-doped silicon.

An interconnect layer 22 is provided above the interconnect layer 21, with an insulating layer interposed therebetween. The interconnect layer 22 includes, for example, a stack portion formed in a plate-like shape extending along the XY plane and a step portion (not illustrated in FIG. 5) formed in the staircase region STP. The stack portion of the interconnect layer 22 is used as a select gate line SGS. The interconnect layer 22 contains, for example, tungsten.

A plurality of insulating layers and a plurality of interconnect layers 23 are alternately stacked above the interconnect layer 22. Each interconnect layer 23 includes, for example, a stack portion formed in a plate-like shape extending along the XY plane and a step portion (not illustrated in FIG. 5) formed in the staircase region STP. The stack portions of the stacked interconnect layers 23 are, in the order from the side of the semiconductor substrate 20, respectively used as word lines WL0 to WL7. The interconnect layers 23 contain, for example, tungsten.

An interconnect layer 24 is provided above the topmost interconnect layer 23, with an insulating layer interposed therebetween. The interconnect layer 24 is formed in, for example, a plate-like shape extending along the XY plane. The interconnect layer 24 is used as a select gate line SGD. The interconnect layer 24 contains, for example, tungsten.

A plurality of interconnect layers 25 is provided above the interconnect layer 24, with an insulating layer interposed therebetween. The interconnect layers 25 are each formed in, for example, a linear shape extending along the Y direction. The interconnect layers 25 are used as bit lines BL. The interconnect layers 25 are aligned along the X direction in an unillustrated region. The interconnect layers 25 contain, for example, copper.

Each of the memory pillars MP is provided so as to extend along the Z direction, and penetrates the interconnect layers 22 to 24 as well as the insulating layers provided between the interconnect layer 21 and the interconnect layer 24. Each of the memory pillars MP includes, for example, a core film 30, a semiconductor film 31, and a stacked film 32. The core film 30 is provided so as to extend along the Z direction. For example, an upper end of the core film 30 is located above the interconnect layer 24, and a lower end of the core film 30 is located in the interconnect layer 21. The core film 30 contains, for example, an insulator such as silicon oxide. The semiconductor film 31 covers, for example, the periphery of the core film 30. At the lower end of the memory pillar MP, a part of the semiconductor film 31 contacts the interconnect layer 21. The semiconductor film 31 contains, for example, silicon. The stacked film 32 covers the side and bottom surfaces of the semiconductor film 31, except for a portion at which the semiconductor film 31 and the interconnect layer 21 contact.

In the structure of the memory pillar MP shown in FIG. 5, a portion at which the memory pillar MP and the interconnect layer 22 intersect each other functions as a select transistor ST2. The portions at which the memory pillar MP intersects the interconnect layers 23 respectively function as memory cell transistors MT0 to MT7. The portion at which the memory pillar MP intersects the interconnect layer 24 functions as a select transistor ST1.

A columnar contact CV is provided on an upper surface of the semiconductor film 31 in the memory pillar MP. In the region illustrated in FIG. 5, two contacts CV respectively corresponding to two of the six memory pillars MP are shown. Another contact CV is coupled, in an unillustrated region, to the other memory pillar MP which does not overlap the member SHE and to which a contact CV is not coupled in the illustrated region.

A top surface of the contact CV is in contact with one of the interconnect layers 25, namely, one of the bit lines BL. A single contact CV is coupled to one of the interconnect layers 25 in each of the spaces partitioned by the members SLT and SHE. That is, a single memory pillar MP is electrically coupled to each of the interconnect layers 25 in the region between adjacent members SLT and SHE, and a single memory pillar MP is electrically coupled to each of the interconnect layers 25 in the region between two adjacent members SHE.

The member SLT is formed, for example, so as to spread along the XZ plane, and to divide the interconnect layers 22 to 24 as well as the insulating layers provided between the interconnect layer 21 and the interconnect layer 24.

In the member SLT, the contact LI is provided so as to spread along the XZ plane, and the spacer SP is provided between the contact LI and the interconnect layers 22 to 24. An upper end of the contact LI is located, for example, in the insulating layer between the interconnect layer 24 and the interconnect layer 25. A lower end of the contact LI contacts, for example, the interconnect layer 21. The contact LI may be omitted, depending on the structure of the memory cell array 10.

Each member SHE is formed in, for example, a plate-like shape spreading along the XZ plane so as to divide the interconnect layer 24. An upper end of the member SHE is located in the insulating layer between the interconnect layer 24 and the interconnect layer 25. A lower end of the member SHE is located, for example, in the insulating layer between the topmost interconnect layer 23 and the interconnect layer 24. The member SHE contains, for example, an insulator such as silicon oxide. The upper end of the member SHE may be either aligned or not aligned with an upper end of the member SLT. The upper end of the member SHE may be either aligned or not aligned with an upper end of the memory pillar MP.

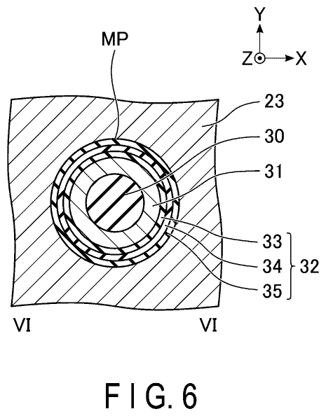

FIG. 6 is a cross-sectional diagram taken along line VI-VI of FIG. 5, showing an example of a cross-sectional structure of a memory pillar in the semiconductor memory device according to the embodiment. More specifically, FIG. 6 shows a cross-sectional structure of a memory pillar MP in a layer parallel to the surface of the semiconductor substrate 20 and including the interconnect layer 23. As shown in FIG. 6, the stacked film 32 includes, for example, a tunnel insulating film 33, a charge storage film 34, and a block insulating film 35.

In a cross section including the interconnect layer 23, the core film 30 is provided at, for example, the center of the memory pillar MP. The semiconductor film 31 surrounds the side surface of the core film 30. The tunnel insulating film 33 surrounds the side surface of the semiconductor film 31. The charge storage film 34 surrounds the side surface of the tunnel insulating film 33. The block insulating film 35 surrounds the side surface of the charge storage film 34. The interconnect layer 23 surrounds the side surface of the block insulating film 35.

The semiconductor film 31 is used as a channel (current path) of each of the memory cell transistors MT0 to MT7 and the select transistors ST1 and ST2. Both of the tunnel insulating film 33 and the block insulating film 35 contain, for example, silicon oxide. The charge storage film 34 is equipped with a function of storing charge, and contains, for example, silicon nitride. With the above-described configuration, each memory pillar MP may function as a single NAND string NS.

### 1.4.3 Hookup Region

### 1.4.3.1 Planar Layout

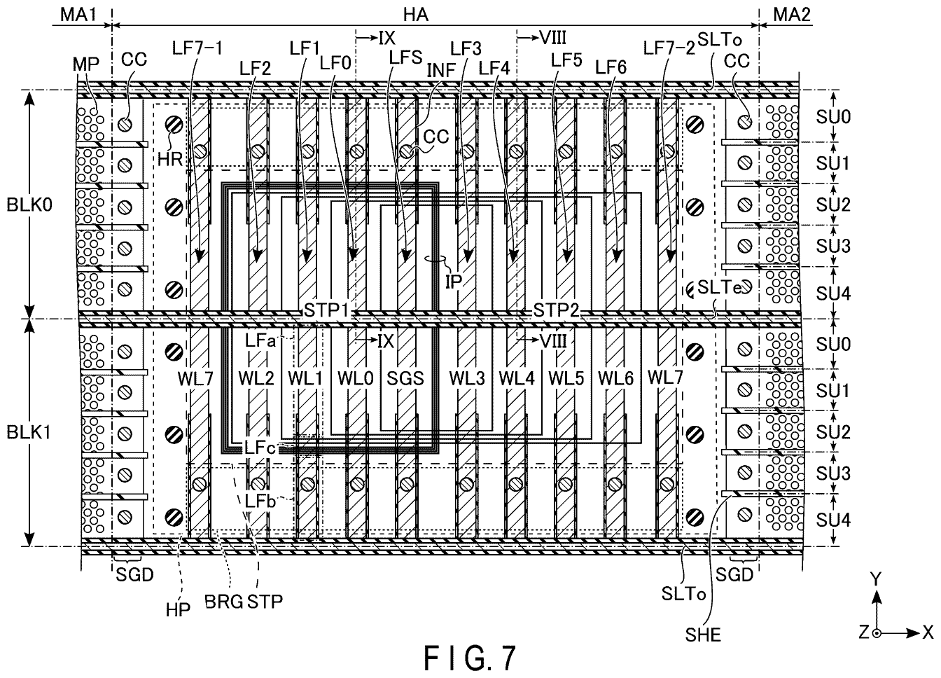

FIG. 7 is a plan view showing an example of a planar layout of the hookup region in the memory cell array included in the semiconductor memory device according to the embodiment. FIG. 7 shows not only the hookup portion HP corresponding to the two blocks BLK0 and BLK1 in the hookup region HA, but also portions of the memory regions MA1 and MA2 in the neighborhood.

As shown in FIG. 7, the memory cell array 10 includes, in the hookup region HA, a plurality of contacts CC, a plurality of lift portions LFS and LF0 to LF7, a plurality of insulating films INF, and a plurality of supporting pillars HR.

In the hookup region HA, a step is provided between the word line WL7 and the select gate line SGD on the outer side of the staircase region STP in the X direction. In the staircase region STP, each of the select gate line SGS and the word lines WL0 to WL7 includes a terrace portion that does not overlap the upper interconnect layers. The terrace portions in the hookup region HA are in a shape similar to steps, terraces, rimstone, etc.

In the staircase region STP, a single stadium-shaped staircase structure is formed in each hookup portion HP. The stadium-shaped staircase structure has a structure in which a terrace portion of an upper interconnect layer surrounds a terrace portion of a lower interconnect layer on all four sides in a plan view. The stadium-shaped staircase structure is provided across the member SLTe, and has a structure symmetrical to the member SLTe.

In the staircase region STP, a plurality of interconnect layers include an inclined portion IP. The inclined portion IP is a step formed in a rectangular shape in a plan view and includes end portions of a plurality of (four in the example shown in FIG. 7) continuous interconnect layers. In the inclined portion IP, the end portions of the continuous interconnect layers are inclined at an inclination angle substantially identical to a diagonal direction in the YZ plane, and form a slope. The inclined portion IP is provided so as to surround a portion of the stadium-shaped staircase structure that is deviated to the memory region MA1 from the center in the X direction. In the staircase region STP, the stadium-shaped staircase structure is divided into staircase structures STP1 and STP2 by the inclined portion IP. The staircase regions STP1 and STP2 are aligned in the X direction.

The staircase region STP1 includes an inner region of the inclined portion IP. In the staircase region STP1, terrace portions of the select gate line SGS and the word lines WL0 to WL2 and WL7 are provided. The terrace portions of the select gate line SGS and the word lines WL0 to WL2 are provided in the inner region of the inclined portion IP, and the terrace portion of the word line WL7 is provided in a region between the memory region MA1 and the inclined portion IP on the outer side of the inclined portion IP. Specifically, the terrace portion of the select gate line SGS is surrounded by the terrace portion of the word line WL0. The terrace portion of the word line WLi is surrounded by the terrace portion of the word line WL (i+1) (0≤i≤2). The terrace portion of the word line WL2 is surrounded by the terrace portion of the word line WL7. That is, in the the staircase region STP1, stadium-shaped staircase structure includes staircase portions in three directions: a direction going from the terrace portion of the select gate line SGS toward the side of the memory region MA1 and two directions respectively going toward the side of the two bridge regions BRG interposing the staircase region STP1 in the Y direction. Hereinafter, the staircase portion going from the terrace portion of the select gate line SGS toward the side of the memory region MA1, including the inclined portion IP arranged in between, will be referred to as a “first X-direction staircase portion”.

The staircase region STP2 is a region between the memory region MA2 and the inclined portion IP on the outer side of the inclined portion IP. In the staircase region STP2, the terrace portions of the word lines WL3 to WL7 are provided. Specifically, the terrace portion of the word line WLj is surrounded by the word line WL (j+1) (3≤j≤6). That is, in the staircase region STP2, the stadium-shaped staircase structure includes staircase portions in each of three directions: a direction going from the terrace portion of the word line WL3 toward the side of the memory region MA2 and two directions respectively going toward the side of the two bridge regions BRG interposing the staircase region STP2 in the Y direction. Hereinafter, the staircase portion going from the terrace portion of the word line WL3 toward the memory region MA2 will be referred to as a “second X-direction staircase portion”.

Hereinafter, in each of the staircase regions STP1 and STP2, the staircase portion going from the terrace portion of each interconnect layer toward the side of the bridge region BRG will be referred to as a “Y-direction staircase portion”. Also, a portion of the inclined portion IP that is inclined in the Y direction will be referred to as a “Y-direction inclined portion”. The stadium-shaped staircase structure includes, in each block BLK, a first X-direction staircase portion, a second X-direction staircase portion, a Y-direction staircase portion, and a Y-direction inclined portion.

The terrace portions of the select gate line SGS and the word lines WL0 to WL2 and WL7 corresponding to the first X-direction staircase portion and the terrace portions of the word lines WL3 to WL7 corresponding to the second X-direction staircase portion have a greater X-direction width than the diameters of a plurality of contacts CC, to be described later. Hereinafter, the terrace portions of the select gate line SGS and the word lines WL0 to WL2 and WL7 corresponding to the first X-direction staircase portion and the terrace portions of the word lines WL3 to WL7 corresponding to the second X-direction staircase portion will be collectively referred to as a “hookup terrace portion”. In the hookup terrace portion, the word lines WL7, WL2, WL1, WL0, the select gate line SGS, and the word lines WL3, WL4, WL5, WL6, and WL7 are arranged in this order along the X direction. That is, the staircase structure formed by the hookup terrace portion of the select gate line SGS and the word lines WL0, WL1, WL2, and WL7 of the stacked interconnects has a structure going along the X direction toward the memory region MA1. Also, the staircase structure formed by the hookup terrace portion of the word lines WL3, WL4, WL5, WL6, and WL7 of the stacked interconnects has a structure going along the X direction toward the memory region MA2.

The lift portions LFS and LF0 to LF6, respectively corresponding to the select gate line SGS and the word lines WL0 to WL6, are provided in each hookup portion HP. The lift portion LF7-1 corresponding to the word line WL7 is provided on the side of the memory region MA1 in each hookup portion HP. The lift portion LF7-2 corresponding to the word line WL7 is provided on the side of the memory region MA2 in each hookup portion HP. Hereinafter, the lift portions LF7-1 and LF7-2 will be collectively referred to as “lift portions LF7” if they need not be distinguished from each other. The lift portions LFS and LF0 to LF7 are aligned in the X direction so as to be distanced from one another. Each lift portion LF extends in the Y direction in a plan view, and includes a first portion LFa contacting the hookup terrace portion of the corresponding interconnect layer in the staircase region STP, a second portion LFb contacting the corresponding contact CC in the bridge region BRG, and a third portion LFc connecting the first portion LFa and the second portion LFb. The third portions LFc of the lift portions LFS and LF0 to LF6 include portions provided so as to extend along the Y-direction staircase portion. However, the third portion LFc of the lift portion LF7 does not include a portion provided so as to extend along the Y-direction staircase portion, and the first portion LFa, the second portion LFb, and the third portion LFc provided in the lift portion LF7 are located at substantially the same height. The third portions LFc of the lift portions LFS and LF0 to LF2 further include portions provided so as to extend along the Y-direction inclined portion. The lift portions LF are, except for the first portion LFa, provided so as to be electrically isolated from the stacked interconnects. Both end portions of each of the lift portions LF in the Y direction contact two mutually different members SLTo. The lift portion LF is divided in the Y direction by the member SLTe dividing each hookup portion HP into two blocks BLK.

Each of the insulating films INF is provided for a corresponding one of the lift portions LFS and LF0 to LF7. Each insulating film INF is arranged between the stacked interconnects and the second portion LFb of the corresponding lift portion LF, and between the stacked interconnects and the third portion LFc of the corresponding lift portion LF. That is, each insulating film INF provides insulation between all the interconnect layers except the interconnect layer contacted by the first portion LFa of the corresponding lift portion LF and the corresponding lift portion LF. The lift portions LF and the insulating films INF divide the word line WL7 in the bridge region BRG in the X direction. The lift portion LF7-1 provided on the side of the memory region MA1 and the lift portion LF7-2 provided on the side of the memory region MA2 are electrically coupled with a contact CC, to be described later, and an interconnect layer, not illustrated, interposed therebetween above the contact CC.

A portion of the word line WL7 in the bridge region BRG interposed by the lift portions LF and the insulating films INF in the X direction is brought to an electrically floating state.

The contacts CC are respectively provided for the select gate lines SGS and SGD and the word lines WL0 to WL7. The contact CC corresponding to the select gate line SGD is provided on an upper surface of the select gate line SGD at an end portion of the hookup region HA. Each of the contacts CC corresponding to the select gate line SGS and the word lines WL is provided on an upper surface of a corresponding lift portion LF in the bridge region BRG. The lengths of the contacts CC corresponding to the select gate line SGS and the word lines WL in the Z direction are substantially identical.

The select gate line SGS and the word lines WL0 to WL7 are electrically coupled to the row decoder module 15 with a corresponding contact CC and a set of lift portions LFS and LF0 to LF7. The select gate line SGD is electrically coupled to the row decoder module 15 with a corresponding contact CC interposed therebetween.

A plurality of support pillars HR is suitably arranged in the hookup region HA except for portions where the members SLT are to be formed, portions where the lift portions LFS and LF0 to LF7 are to be formed, and portions where the contacts CC are to be formed.

### 1.4.3.2 Cross-Sectional Structure

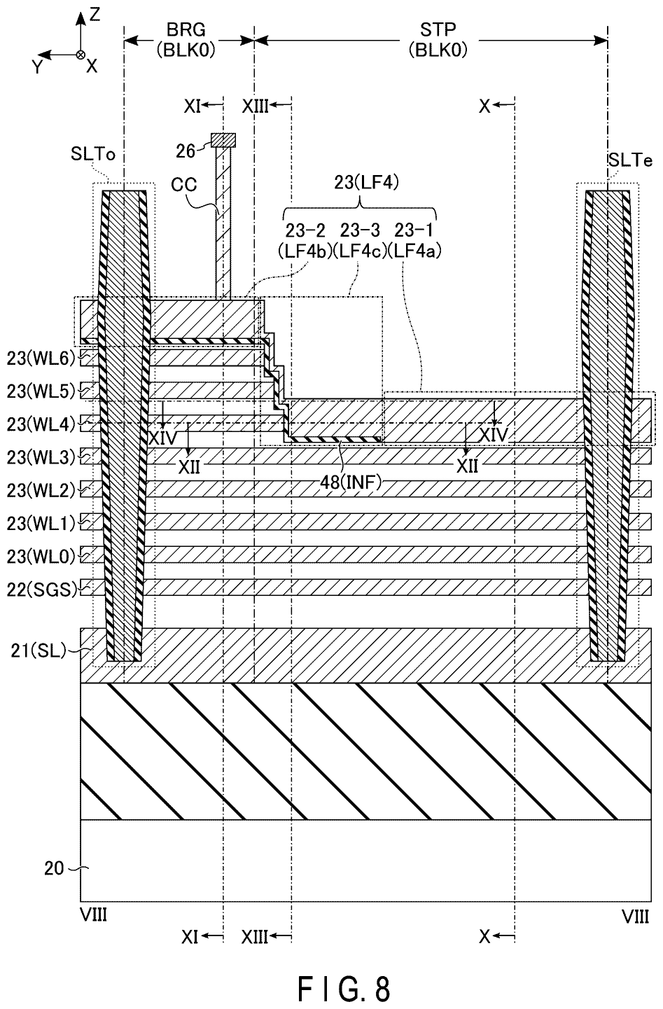

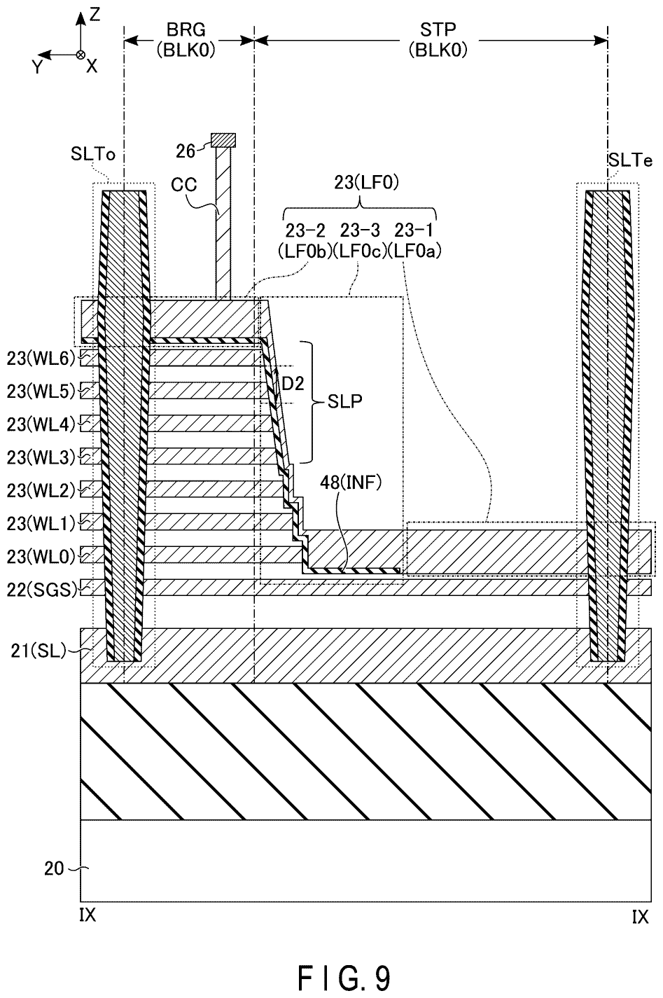

FIG. 8 is a cross-sectional diagram taken along line VIII-VIII of FIG. 7, showing an example of a cross-sectional structure of the hookup region of the memory cell array included in the semiconductor memory device according to the embodiment. FIG. 9 is a cross-sectional diagram taken along line IX-IX of FIG. 7, showing an example of a cross-sectional structure of the hookup region of the memory cell array included in the semiconductor memory device according to the embodiment. Each of FIGS. 8 and 9 shows a YZ cross section of the staircase region STP, the bridge region BRG, the contact CC, and the members SLTo and SLTe of the block BLK0. FIG. 8 corresponds to a cross section of the lift portion LF4 corresponding to the word line WL4. FIG. 9 corresponds to a cross section of the lift portion LF0 corresponding to the word line WL0. Hereinafter, a cross-sectional structure of the hookup region HA will be described with reference to FIGS. 8 and 9 by taking the word lines WL4 and WL0 as representatives.

For the interconnect layer 22, in the staircase region STP, a step portion that functions as a lift portion LFS corresponding to the select gate line SGS is provided. The step portion of the lift portion LFS has a shape that rises upward in a staircase manner from the hookup terrace portion. Hereinafter, portions of the step portion of the lift portion LFS corresponding to the first portion LFSa, the second portion LFSb, and the third portion LFSc will be respectively referred to as portions “22-1”, “22-2”, and “22-3”.

For the interconnect layers 23, step portions that respectively function as lift portions LF0 to LF7 corresponding to the word lines WL0 to WL7 in the staircase region STP are provided. Similarly to the step portion of the lift portion LFS, the step portions of the lift portions LF0 to LF7 have a shape that rises upward in a staircase manner from the hookup terrace portion, except for the topmost interconnect layer 23 at which the first portion LFa, the second portion LFb, and the third portion LFc of the lift portion LF7 are located at substantially the same height. Hereinafter, portions of the lift portion LFk to be the word line WLk (where 0≤k≤7) corresponding to the first portion LFka, the second portion LFkb, and the third portion LFkc will be respectively referred to as portions “23-1”, “23-2”, and “23-3”.

The memory cell array 10 further includes a plurality of interconnect layers 26 and a plurality of insulators 48. Each of the interconnect layers 26 is provided for a corresponding one of the interconnect layers 22 and 23, and is configured to provide coupling between the contact CC and the row decoder module 15. Each of the insulators 48 is provided for a corresponding one of the interconnect layers 22 and 23, and is used as an insulating film INF.

As shown in FIG. 9, each of the portion 22-3 of the interconnect layer 22 and the portion 23-3 of the interconnect layers 23 to be the word lines WL0 to WL2 includes a slope SLP. Each slope SLP is provided so as to extend along a slanted structure of the Y-direction inclined portion of the stacked interconnects, and has a shape that is slanted downward from the topmost interconnect layer 23 toward the staircase-shaped step of the portions interconnect layer 22 and the interconnect layers 23 corresponding to the word lines WL0 to WL2.

The structures of the stacked interconnects, the lift portions LFS and LF0 to LF7, and the insulating films INF in the staircase region STP and the bridge region BRG will be described with reference to FIGS. 8, 10, 11, 12, 13, and 14.

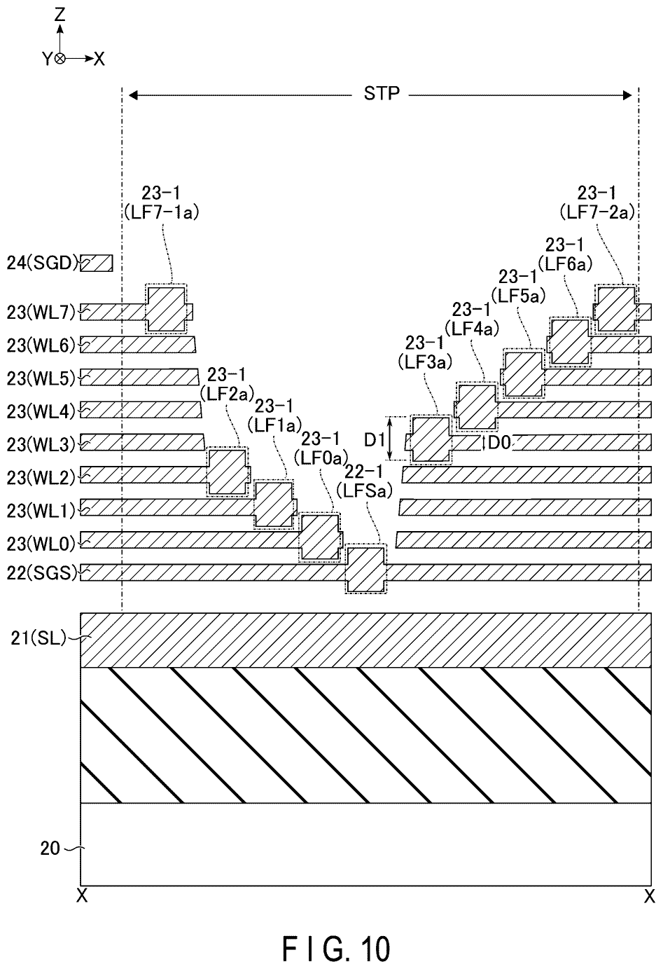

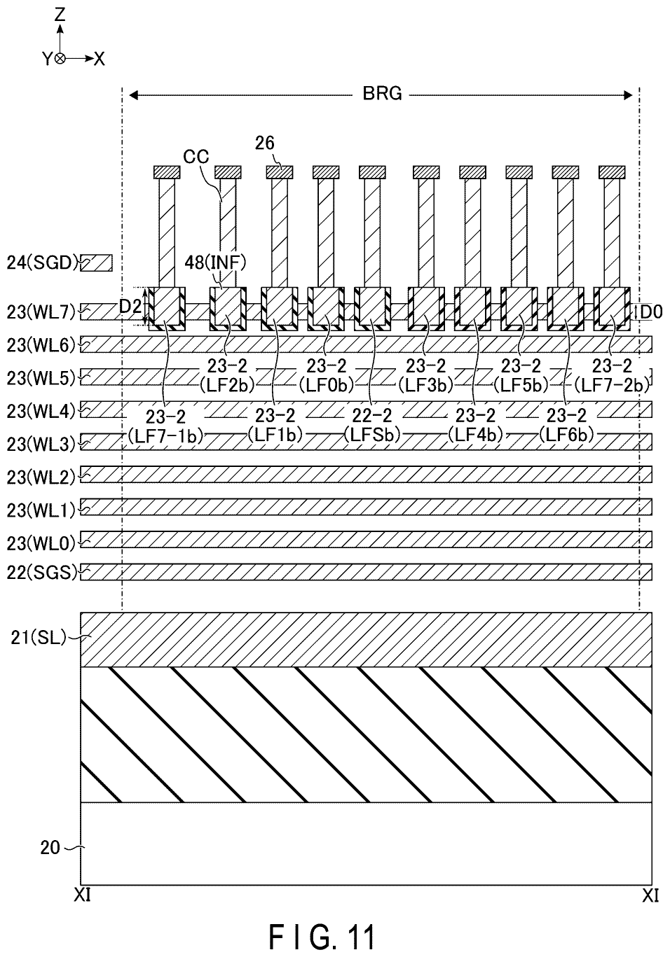

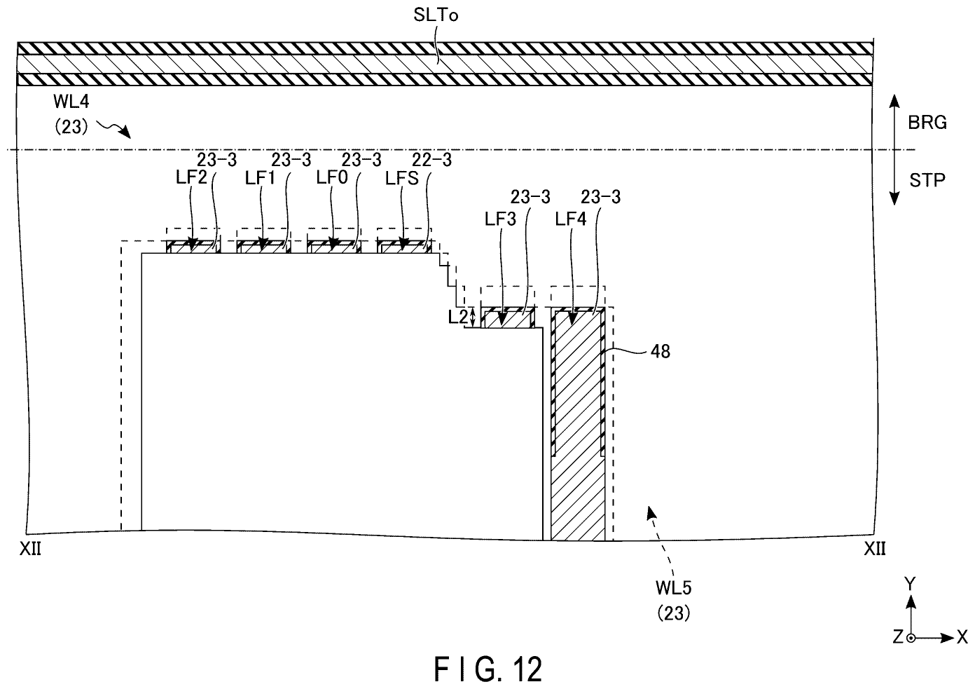

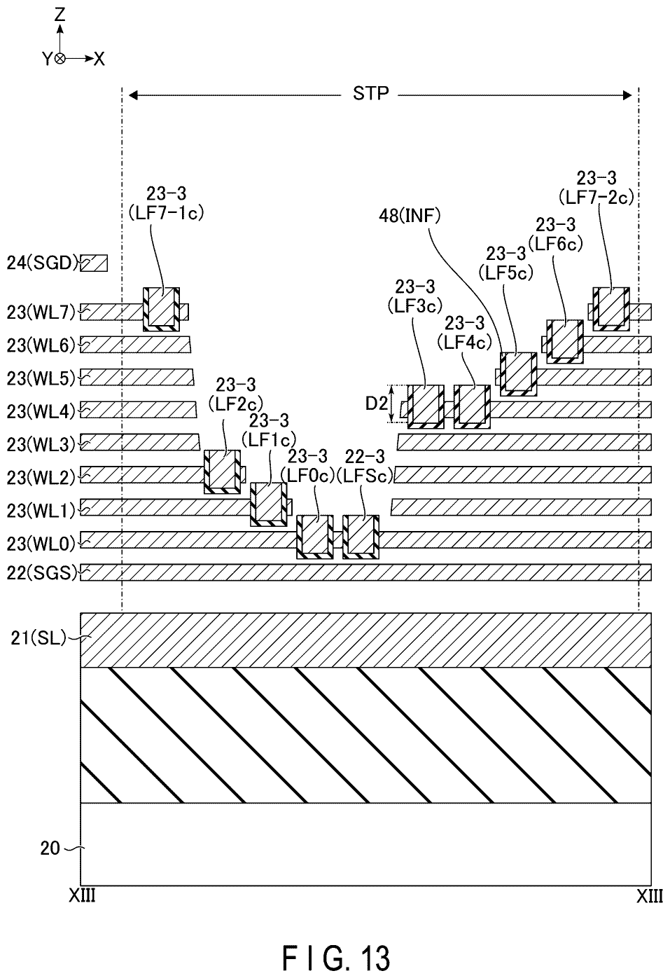

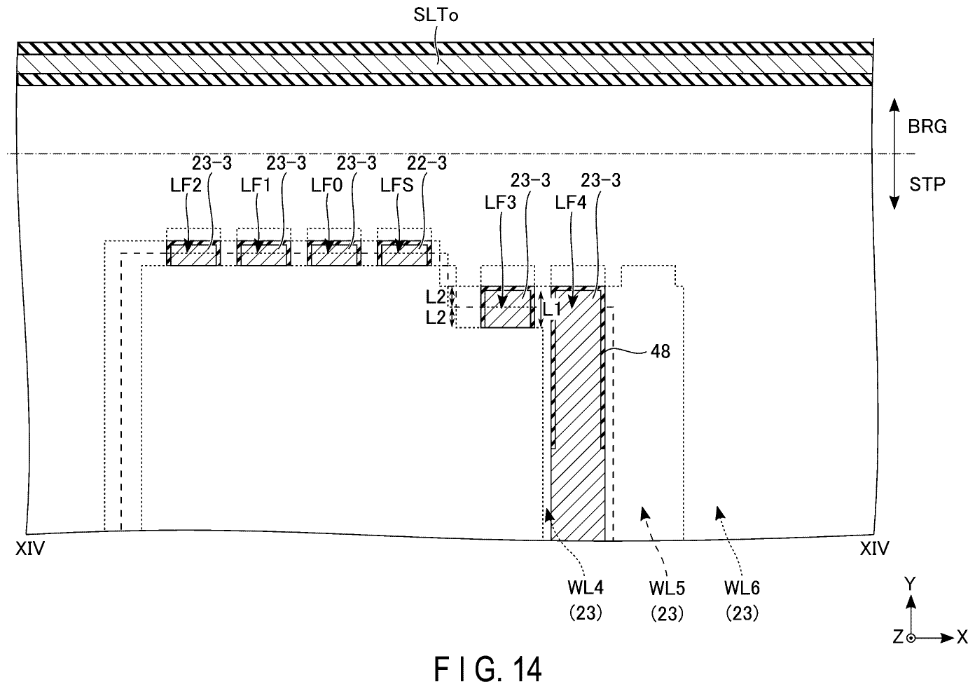

Each of FIGS. 10, 11, and 13 shows an example of a cross-sectional structure of the hookup region of a memory cell array included in the semiconductor memory device according to the embodiment. FIG. 10 is a cross-sectional view taken along line X-X of FIG. 8. FIG. 10 corresponds to a cross-sectional structure including first portions LFa of the lift portions LFS and LF0 to LF7. FIG. 11 is a cross-sectional view taken along line XI-XI of FIG. 8. FIG. 11 corresponds to a cross-sectional structure including second portions LFb of the lift portions LFS and LF0 to LF7. FIG. 13 is a cross-sectional view taken along line XIII-XIII of FIG. 8. FIG. 13 corresponds to a cross-sectional structure including portions of the third portions LFc of the lift portions LFS and LF0 to LF7 extending in the Z direction. Each of FIGS. 12 and 14 shows an example of a

planar layout of the hookup region of the memory cell array included in the semiconductor memory device according to the embodiment. FIG. 12 is a plan view taken along line XII-XII of FIG. 8. FIG. 12 corresponds to a planar structure including the interconnect layer 23 corresponding to the word line WL4. FIG. 14 is a plan view taken along line XIV-XIV of FIG. 8. FIG. 14 corresponds to a planar structure including portions of the third portions LFc of the lift portions LFS and LF0 to LF4 extending in the Y direction. Note that, in FIG. 12, the position at which the interconnect layer 23 corresponding to the word line WL4 is provided in a planar view is denoted by the solid line, and the position at which the interconnect layer 23 corresponding to the word line WL5 is provided in a planar view is denoted by the dotted line. In FIG. 14, the positions at which the interconnect layers 23 corresponding to the word lines WL4, WL5, and WL6 are provided in a planar view is denoted by the dotted lines.

Hereinafter, the structure of a lift portion LF in a single block BLK will be described.

The structure corresponding to the first portion LFa of each lift portion LF will be described. As shown in FIGS. 8 and 10, the portions 22-1 and 23-1 extend in the Y direction in the hookup terrace portion of each of the interconnect layers 22 and 23.

The portion 22-1 is continuous with the stack portion of the interconnect layer 22 in the X direction. A lower surface of the portion 22-1 is located between an upper surface of the interconnect layer 21 and a lower surface of the stack portion of the interconnect layer 22. An upper surface of the portion 22-1 is located at substantially the same height as a lower surface of the stack portion of the bottommost interconnect layer 23.

The portion 23-1 is continuous with the stack portion of the corresponding interconnect layer 23 in the X direction. A lower surface of each portion 23-1 is located between a lower surface of the stack portion of the corresponding interconnect layer 23 and an upper surface of the stack portion of the interconnect layer 22 or 23 one layer below the corresponding interconnect layer 23. An upper surface of each of the portions 23-1 is located at substantially the same height as a lower surface of the stack portion of the interconnect layer 23 one layer above the corresponding interconnect layer 23. However, the upper surface of the portion 23-1 corresponding to the topmost interconnect layer 23 is located between the upper surface of the stack portion of the topmost interconnect layer 23 and the lower surface of the interconnect layer 24.

The thicknesses of the portions 22-1 and 23-1 in the Z direction are substantially identical. The thickness D1 of the portions 22-1 and 23-1 in the Z direction is greater than a thickness DO of the stack portion of the interconnect layers 22 and 23.

Next, the structure corresponding to the second portion LFb of each lift portion LF will be described. As shown in FIGS. 8 and 11, each of the portions 22-2 and 23-2 extends in the Y direction in the bridge region BRG.

A lower surface of each of the portions 22-2 and 23-2 is located between a lower surface of the stack portion of the topmost interconnect layer 23 and an upper surface of the stack portion of the second topmost interconnect layer 23. An upper surface of each of the portions 22-2 and 23-2 is located at substantially the same height as an upper surface of the portion 23-1 of the topmost interconnect layer 23.

The thicknesses of the portions 22-2 and 23-2 in the Z direction are substantially identical. For example, the thickness D2 of each of the portions 22-2 and 23-2 in the Z direction is greater than a thickness D0 of the stack portion of each of the interconnect layers 22 and 23, and is substantially identical to a length obtained by subtracting the thickness of the insulator 48 in the Z direction from the thickness D1 of each of the portions 22-1 and 23-1 in the Z direction.

Each of the portions 22-2 and 23-2 includes a portion overlapping the stack portion of the topmost interconnect layer 23 as viewed in the X direction. A contact CC is provided on an upper surface of each of the portions 22-2 and 23-2.

The interconnect layers 26 are respectively provided above the contacts CC each coupled to the portions 22-2 and 23-2, and are coupled to the corresponding contacts CC. The interconnect layers 26 are electrically coupled to the row decoder module 15, and are located at, for example, the same layer as the interconnect layer 25. Thereby, electrical coupling between each of the interconnect layers 22 and 23 and the row decoder module 15 is provided via the contacts CC and the interconnect layers 26.

As shown in FIG. 11, in the bridge region BRG, each insulator 48 has a gutter-like shape, and extends in the Y direction so as to surround the portion 22-2 or 23-2 of the corresponding interconnect layer 22 or 23 from three directions, namely, both side surfaces and the lower surface in the X direction. In the bridge region BRG, each insulator 48 provides insulation between the corresponding portion 22-2 or 23-2 and the topmost interconnect layer 23.

Lastly, a structure corresponding to the third portion LFc of each lift portion LF will be described. As shown in FIGS. 8, 12, 13, and 14, the portion 22-3 and the portions 23-3 of the interconnect layers 23 other than the interconnect layer 23 to be the word line WL7 alternately extend in the Y direction and the Z direction so as to extend along the Y-direction staircase portion, except for the slope SLP included in the step portions of the interconnect layer 22 and some of the interconnect layers 23. As shown in FIG. 9, the portion 22-3 and the portions 23-3 respectively corresponding to the word lines WL0 to WL2 extend, in the slope SLP, in a direction going toward the bridge region BRG so as to extend along the Y-direction inclined portion. The portion 22-3 provides continuous coupling between the portions 22-1 and 22-2. The portions 23-3 provide continuous coupling between the corresponding portions 23-1 and 23-2.

As shown in FIG. 12, the portion 22-3 overlaps the stack portion of each of the interconnect layers 22 and 23 as viewed in the X direction. Each portion 23-3 overlaps the stack portion of the interconnect layer 23 at the same layer as or above the corresponding interconnect layer 23, as viewed in the X direction. Portions of the portions 22-3 and 23-3 overlapping the stack portion of the upper interconnect layer 23 as viewed in the X direction correspond to the portions extending in the Z direction.

The stack portion of each interconnect layer 23 includes, in the terrace portion of the Y-direction staircase portion, a plurality of trench portions cut in the Y direction at positions corresponding to the lift portions LF. The length of each trench portion in the Y direction is, for example, substantially identical to a length L2 in the Y direction of each terrace portion of the Y-direction staircase portion. The portions 22-3 and 23-3 extend in the Z direction in the respective trench portions of the stack portion of each interconnect layer 23.

As shown in FIG. 13, in the terrace portion of the Y-direction staircase portion, the thickness of the portion of each of the portions 22-3 and 23-3 extending in the Z direction is, for example, substantially identical to the thickness D2 in the Z direction of each of the portions 22-2 and 23-2. Each insulator 48 is provided, in the portion of the corresponding interconnect layer 22 or 23 in which the portion 22-3 or 23-3 extends in the Y direction, so as to surround the portion 22-3 or 23-3 from three directions, namely, from both side surfaces and from the lower surface in the X direction.

As shown in FIG. 14, in the terrace portion of the Y-direction staircase portion, a length L1 of each of the portions 22-3 and 23-3 of each layer extending in the Y direction is greater than a length L2 of the terrace portion of the Y-direction staircase portion. The length L1 is obtained by, for example, subtracting the thickness of the insulator 48 from the Y-direction lengths of two terrace portions (2×L2) of the Y-direction staircase portion. In the portion of the interconnect layer 22 or 23 in which the portion 22-3 or 23-3 extends in the Z direction, each insulator 48 is provided so as to surround the corresponding portion 22-3 or 23-3 from three directions, namely, both side surfaces in the X direction and from a side surface in the Y direction on the side of the staircase structure. Each insulator 48 is provided so as to cover top surfaces of the trench portions of the stack portion of the corresponding interconnect layer 22 or 23.

Each of the interconnect layers 23 to be the word lines WL3 to WL6 includes a plurality of trench portions cut in a direction orthogonal to the slope at positions corresponding to the lift portions LFS and LF0 to LF2 in the Y-direction inclined portion. In the trench portions of the interconnect layers 23, the portions 22-3 and the portions 23-3 corresponding to the word lines WL0 to WL2 extend in the slope direction. Portions of the portion 22-3 and the portions 23-3 to be the word lines WL0 to WL2 extending in the slope direction correspond to the slope SLP.

As shown in FIG. 9, the entire length of the slope SLP in the Z direction of each of the portions 22-3 and 23-3 in the Y-direction inclined portion is greater than a length D2 of the portion of each of the portions 22-3 and 23-3 extending in the Z direction in the terrace portion of the Y-direction staircase portion. In the portion of the interconnect layer 22 or 23 in which the portion 22-3 or 23-3 extends in the slope direction, each insulator 48 is provided so as to surround the corresponding portion 22-3 or 23-3 from three directions, namely, from both side surfaces in the X direction and from the slope. Each insulator 48 is provided so as to cover top surfaces of the trench portions of the stack portions of the interconnect layers 23 corresponding to the word lines WL3 to WL6.

### 2. Method of Manufacturing Semiconductor Memory Device

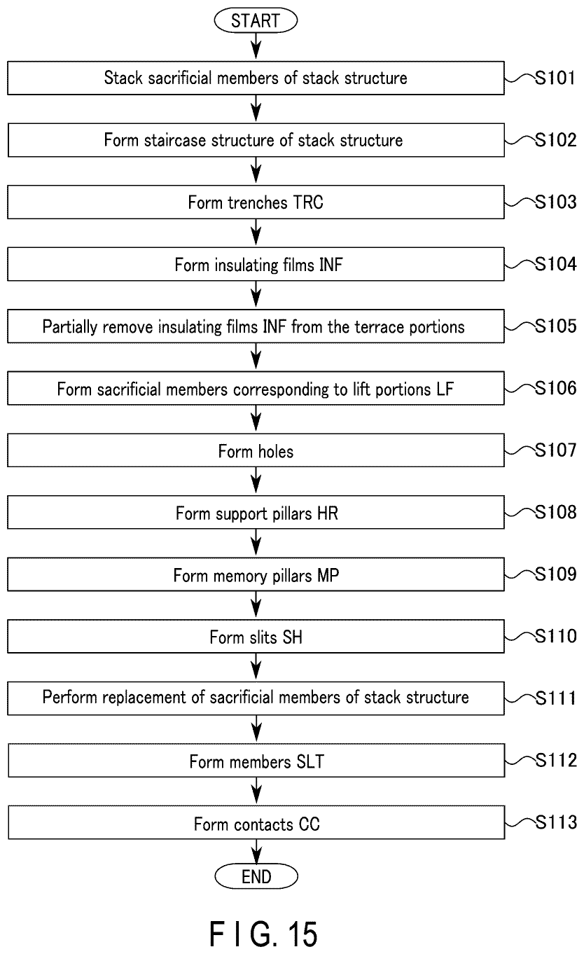

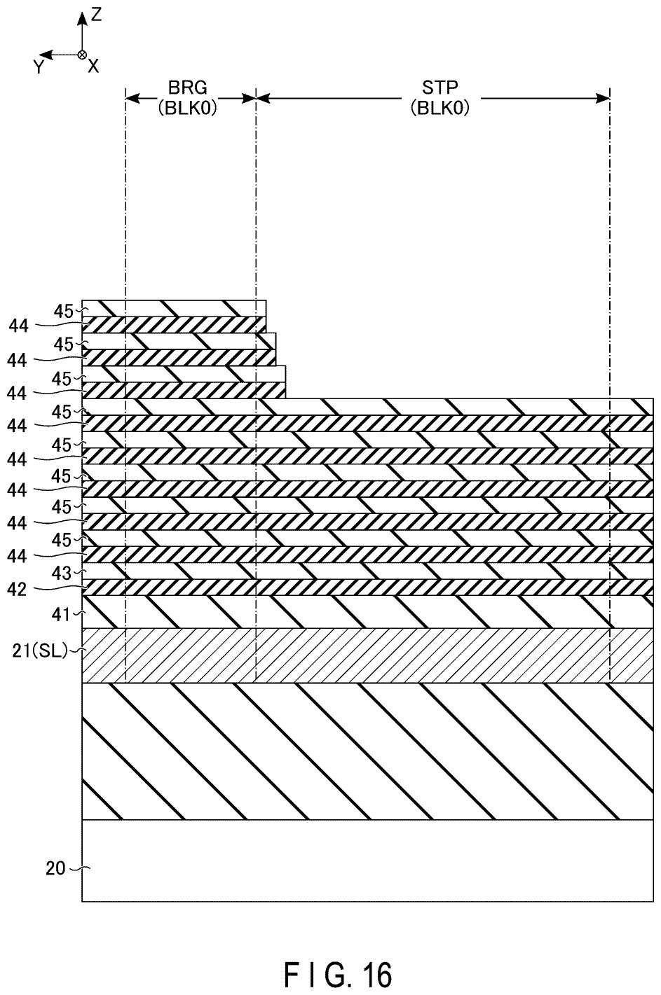

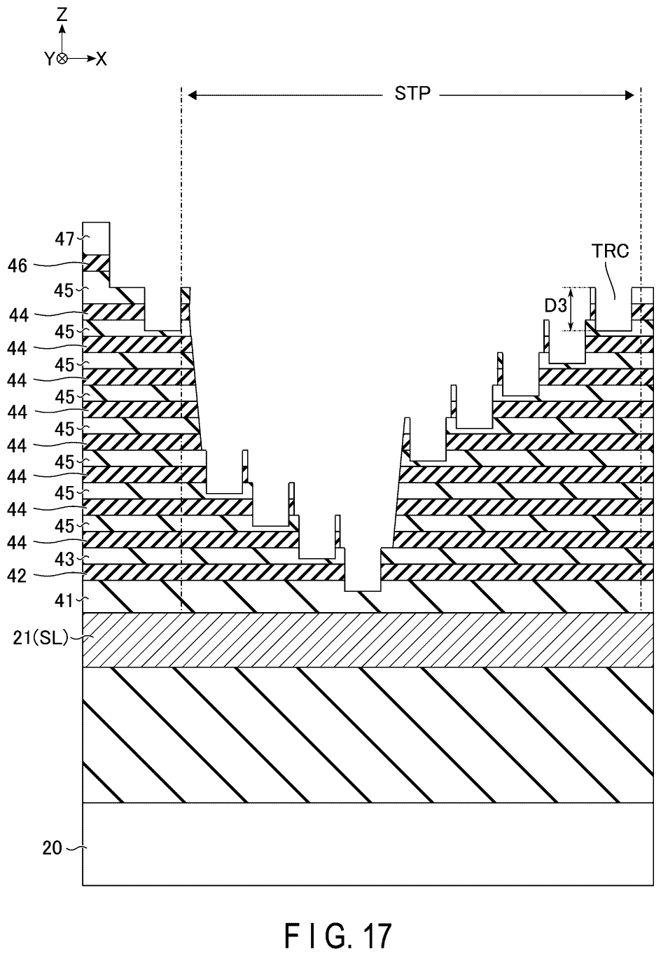

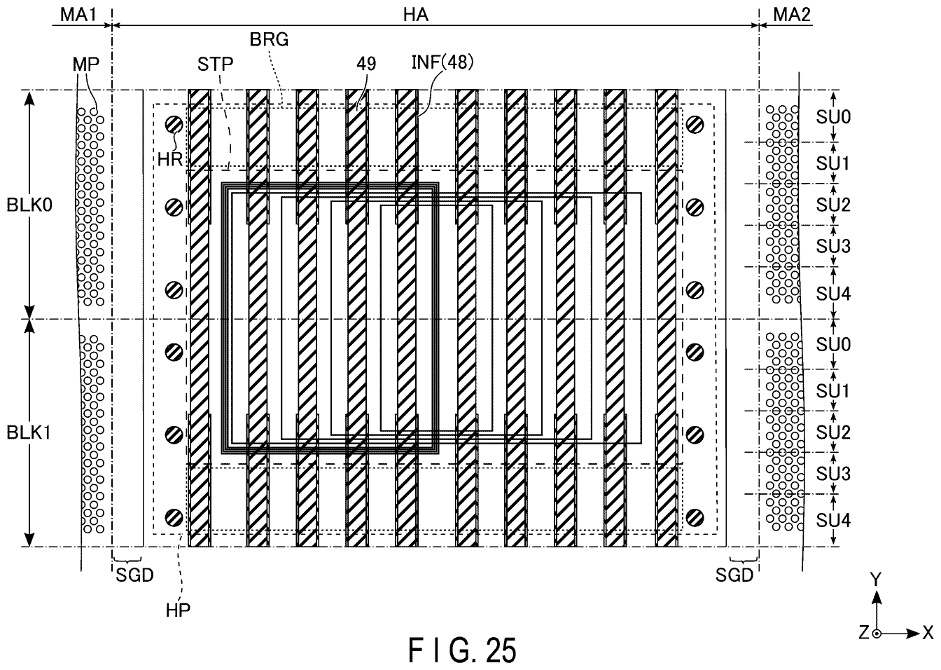

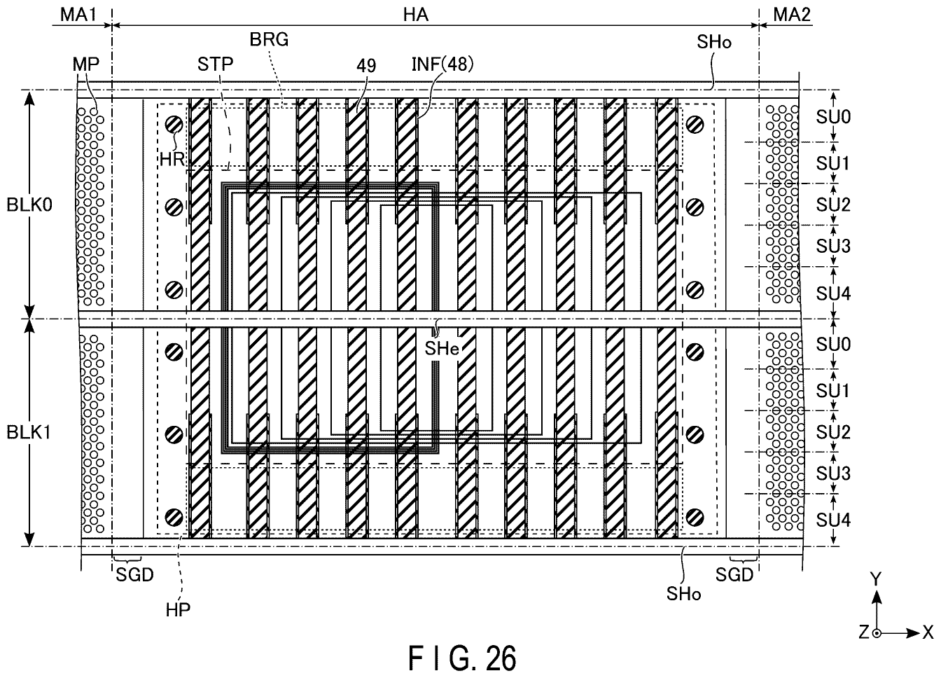

FIG. 15 is a flowchart showing an example of manufacturing steps of a semiconductor memory device according to the embodiment. Each of FIGS. 16 to 28 shows an example of a planar layout or a cross-sectional structure of the semiconductor memory device in the course of manufacturing according to the embodiment. The planar layout shown in FIGS. 25 and 26 shows a region corresponding to FIG. 7. Each of the cross-sectional structures shown in FIGS. 16, 18, 20, 22, 24, 27, and 28 shows a region corresponding to FIG. 8. Each of the cross-sectional structures shown in FIGS. 17, 19, 21, and 23 shows a region corresponding to FIG. 10. As shown in FIG. 15, in the manufacturing steps of the semiconductor memory device 3 according to the embodiment, steps S101 to S113 are sequentially executed. Hereinafter, an example of manufacturing steps of a stacked interconnect structure in the memory cell array 10 in the semiconductor memory device 3 will be described, with reference to FIG. 15.

First, steps S101 and S102 are sequentially executed, and a stadium-shaped staircase structure with a stack structure including sacrificial members 42, 44, and 46 is formed, as shown in FIG. 16.

Briefly speaking, first, peripheral circuits corresponding to the row decoder module 15, the sense amplifier module 16, etc. are formed on the semiconductor substrate 20, and an interconnect layer coupled to the peripheral circuit corresponding to the row decoder module 15 is formed. An insulating layer and an interconnect layer 21 are sequentially stacked above the peripheral circuits. An insulating layer 41 is stacked on the interconnect layer 21. A sacrificial member 42 and an insulating layer 43 are sequentially stacked on the insulating layer 41. A plurality of sacrificial members 44 and a plurality of insulating layers 45 are alternately stacked on the insulating layer 43. A sacrificial member 46 and an insulating layer 47 are sequentially stacked on the topmost insulating layer 45 (S101). The insulating layers 41, 43, 45, and 47 contain, for example, silicon oxide (SiO). The sacrificial members 42, 44, and 46 contain, for example, silicon nitride (SiN).

Thereafter, as shown in FIG. 16, end portions of the stacked sacrificial members 42 and 44 and the insulating layers 43 and 45 stacked immediately above the sacrificial members 42 and 44 are processed into a stadium-like staircase shape in the hookup region HA (S102).

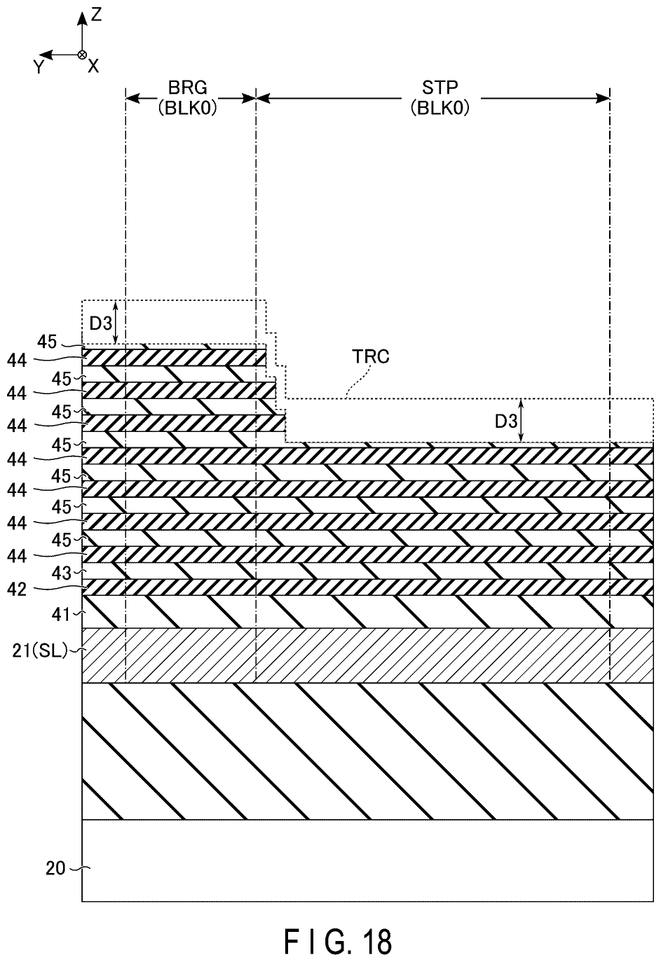

Subsequently, a plurality of trenches TRC is formed (S103). Specifically, as shown in FIGS. 17 and 18, a mask including openings at positions corresponding to the lift portions LF and the insulating films INF is formed by, for example, photolithography. A plurality of trenches TRC is formed by, for example, reactive ion etching using the mask. In FIG. 18 and the drawings to be referred to in the following, the portions corresponding to the trenches TRC are suitably shown by dashed lines. The trenches TRC correspond to the lift portions LFS and LF0 to LF7 and the insulating films INF. The trenches TRC are respectively formed for the interconnect layers 22 and 23. The trench TRC has, in its entirety, a uniform length D3 in the Z direction. For example, the length D3 of the trench TRC in the Z direction is substantially identical to the thickness D1 of the portions 22-1 and 23-1 in the Z direction, and is greater than the thickness D2 of the portions 22-2, 23-2, 22-3, and 23-3 in the Z direction.

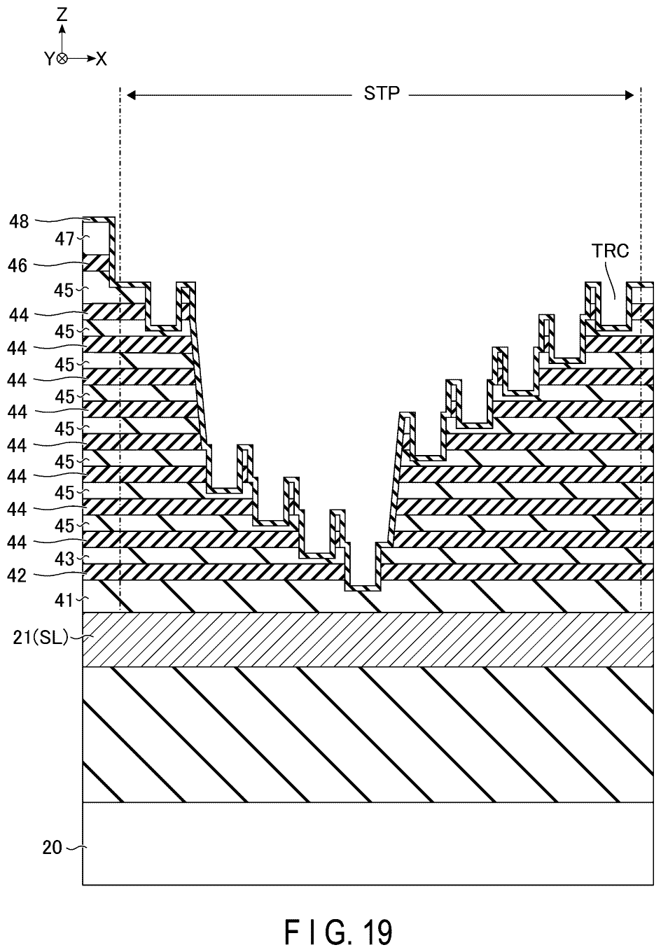

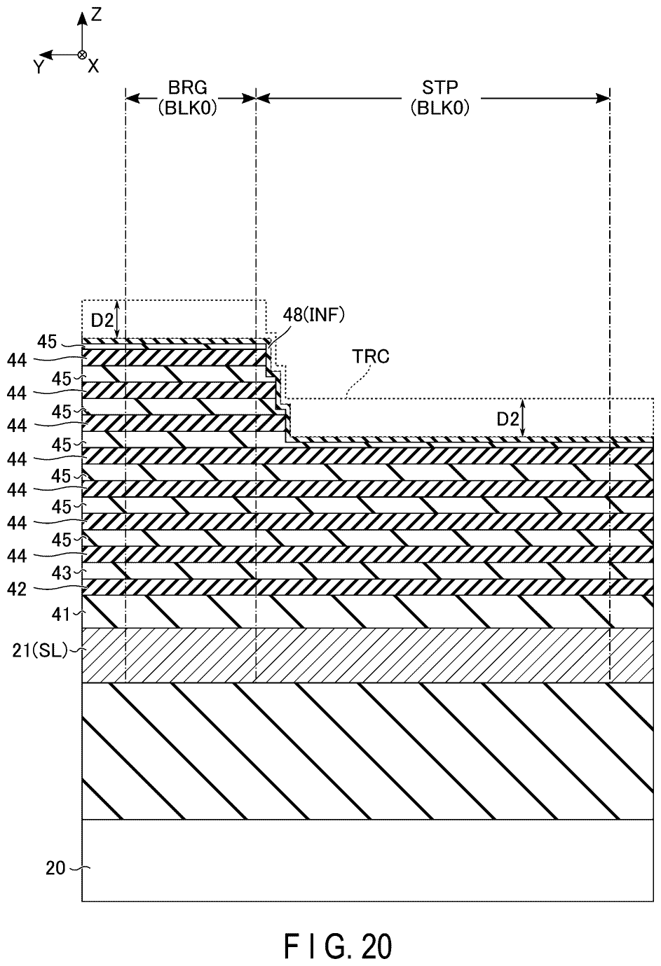

Subsequently, a plurality of insulating films INF is formed (S104). Specifically, as shown in FIGS. 19 and 20, an insulator 48 is formed by, for example, chemical vapor deposition (CVD). The insulator 48 contains, for example, SiO. After formation of the insulating films INF, the trench TRC has a depth substantially identical to the thickness D2 of each of the portions 22-2, 23-2, 22-3, and 23-3 in the Z direction.

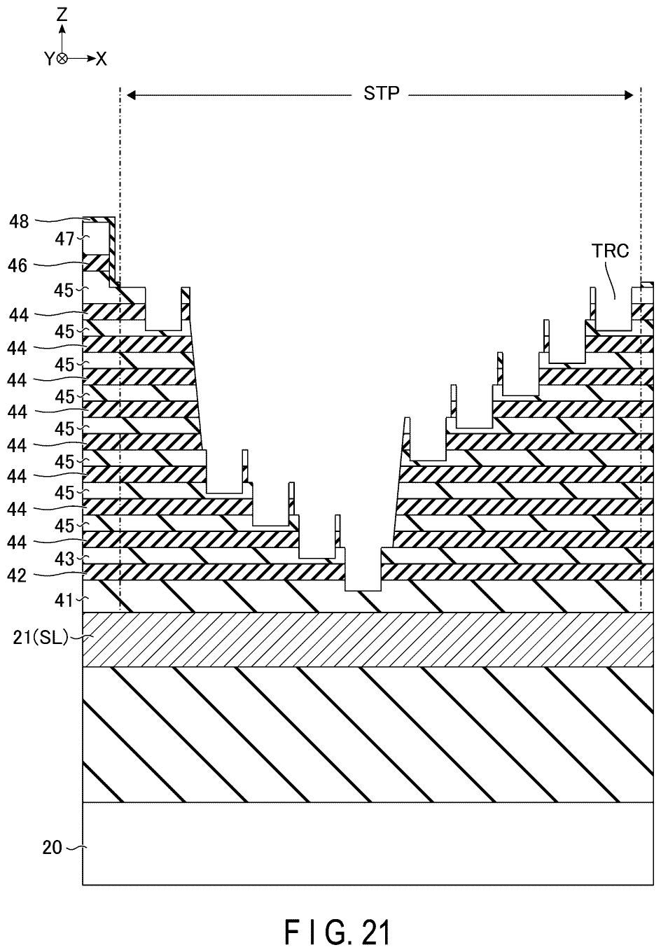

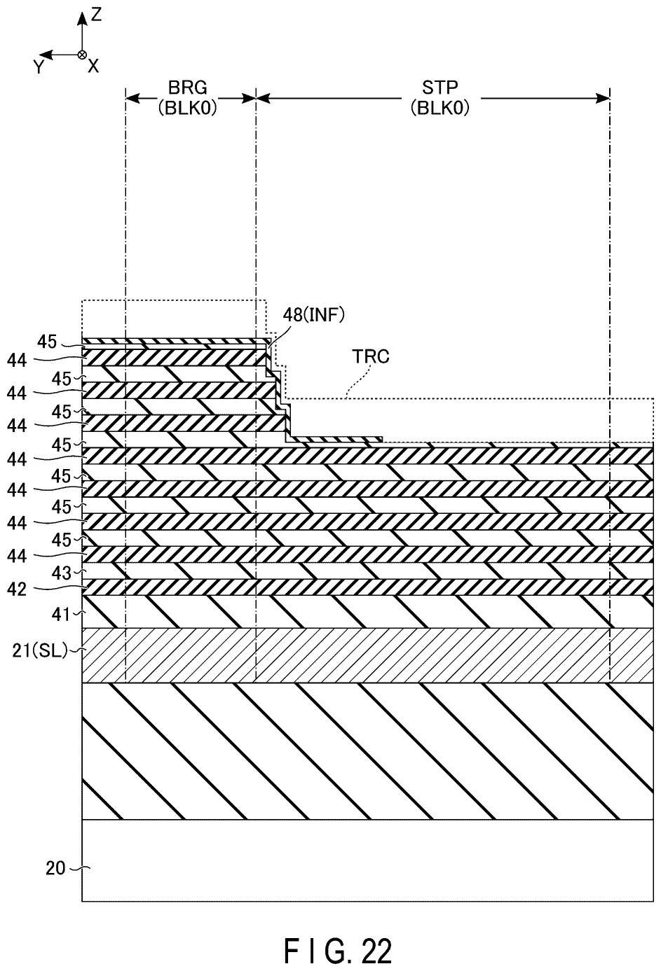

Subsequently, the insulating films INF are partly removed from the terrace portions (S105). Specifically, as shown in FIGS. 21 and 22, a mask including openings at positions corresponding to the first portions LFa of the lift portions LF is formed by, for example, photolithography. Thereafter, the insulator 48 of the hookup terrace portion is partly removed by reactive gas etching, etc. using the mask. At the time of etching, the insulator 48 on the side wall portion of each trench TRC can be selectively removed by depositing carbon. A portion of the trench TRC from which the insulating film INF has been removed is to be a portion at which the first portion LFa of each lift portion LF and a corresponding select gate line SGS or word line WL are coupled.

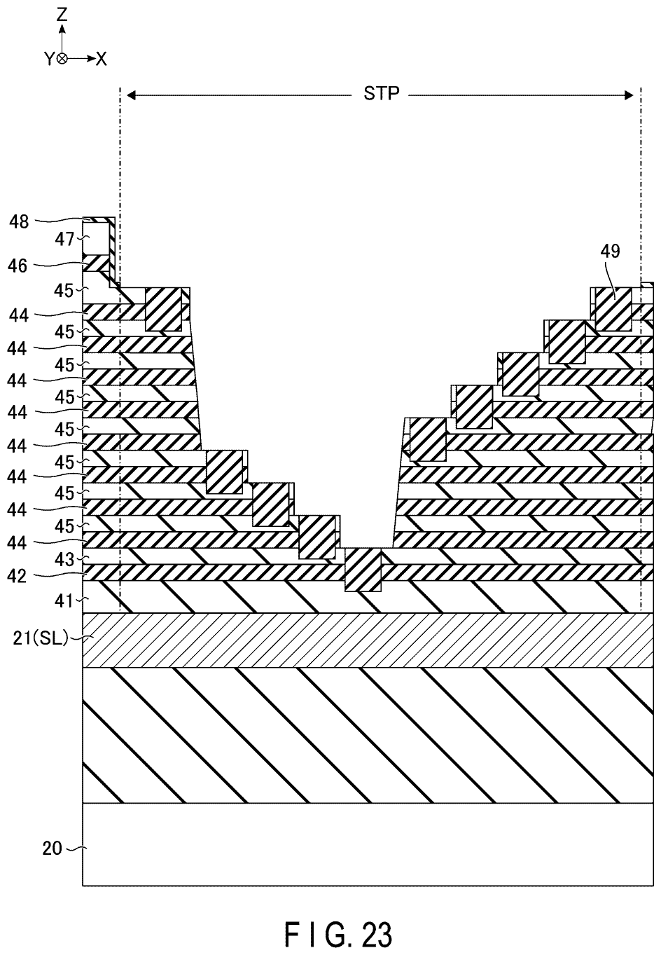

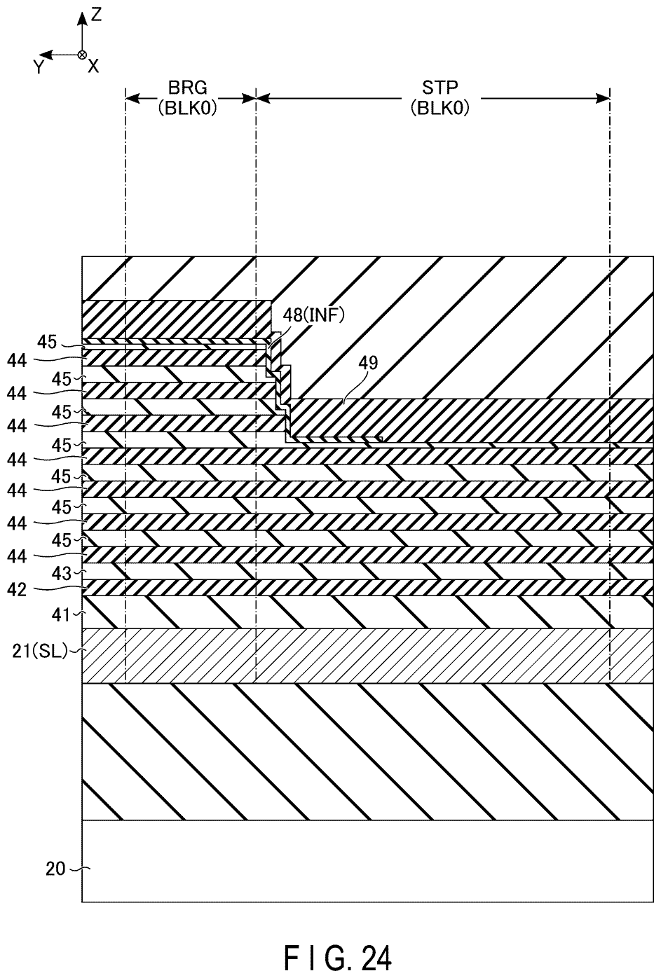

Subsequently, sacrificial members corresponding to the lift portions LF are formed (S106). Specifically, as shown in FIGS. 23 and 24, a sacrificial member 49 is embedded in each trench TRC, and a surface of the stack structure is planarized by an etch-back process, etc. Thereafter, an insulating layer is embedded in the staircase portions in the hookup region HA. An upper surface of the stack structure is planarized by, for example, chemical mechanical polishing (CMP). The sacrificial member 49 contains, for example, SiN. The insulating layer embedded in the staircase portions in the hookup region HA contains, for example, SiO.

Subsequently, steps S107 to S109 are sequentially executed, and a plurality of support pillars HR and a plurality of memory pillars MP are formed, as shown in FIG. 25. The support pillars HR are suitably arranged in the hookup region HA except for the portion where the sacrificial member 49 has been formed, the portions where a plurality of members SLT is to be formed, and the portions where a plurality of contacts CC is to be formed. The memory pillars MP are arranged in, for example, a staggered manner in the memory regions MA1 and MA2.

Briefly speaking, a mask including openings at positions corresponding to the memory pillars MP and the support pillars HR is formed by, for example, photolithography. After that, a plurality of holes corresponding to the memory pillars MP and a plurality of holes corresponding to the support pillars HR are formed by anisotropic etching using the mask (S107). The holes corresponding to the memory pillars MP penetrate, for example, the insulating layers 41, 43, 45, and 47 and the sacrificial members 42, 44, and 46. The holes corresponding to the support pillars HR penetrate, for example, the insulating layers 41, 43, and 45 and the sacrificial members 42 and 44. The interconnect layer 21 is partly exposed at the bottom of each hole.

Subsequently, a mask is formed to bury the holes corresponding to the memory pillars MP, and then a plurality of insulators is formed to bury the holes corresponding to the support pillars HR, thereby forming the support pillars HR (S108). Subsequently, the mask is removed, and a block insulating film 35, a charge storage film 34, and a tunnel insulating film 33 are sequentially formed on side and bottom surfaces of each of the holes corresponding to the memory pillars MP. After that, the block insulating film 35, the charge storage film 34, and the tunnel insulating film 33 are partly removed from the bottom of the hole, and a semiconductor film 31 and a core film 30 are formed in the hole. Thereafter, the core film 30 is partly removed from the top of the hole, and a semiconductor film 31 is formed in a part from which the core film 30 has been removed. Through the above-described process, a memory pillar MP is formed in each of the holes corresponding to the memory pillars MP (S109). Thereafter, an insulating layer is further stacked on a topmost layer of the stack structure so as to cover upper ends of the support pillars HR and the memory pillars MP.

Subsequently, a plurality of slits SH including slits SHo and SHe, as shown in FIG. 26, is formed (S110). Specifically, a mask including openings at positions corresponding to the member SLT is formed by, for example, photolithography. Thereafter, a plurality of slits SH that penetrate, for example, the insulating layers 41, 43, 45, and 47 and the sacrificial members 42, 44, and 46 is formed by anisotropic etching using the mask. The slits SHo and SHe respectively correspond to the members SLTo and SLTe.

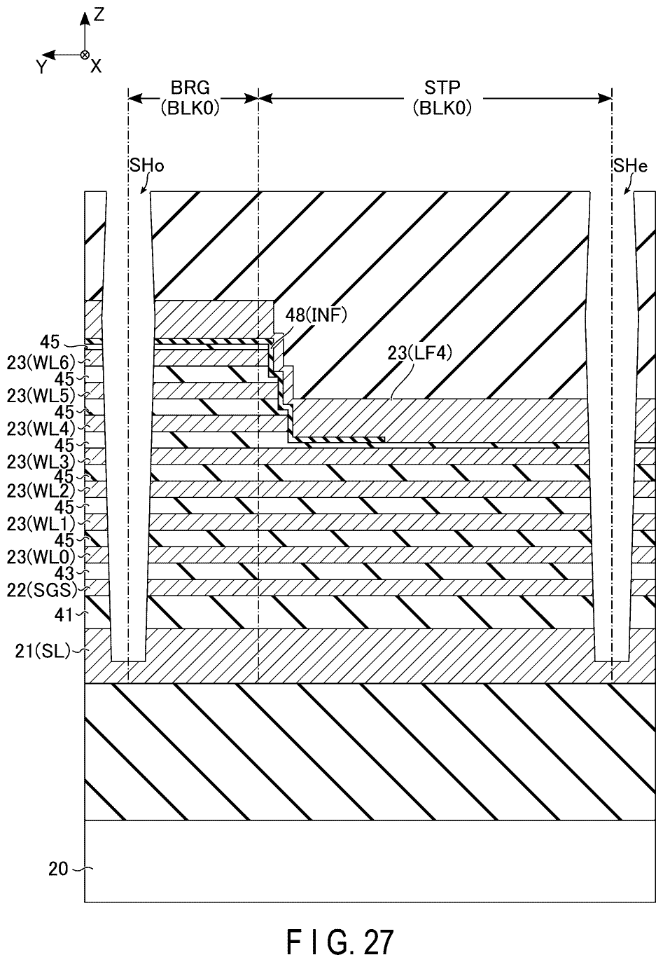

Subsequently, replacement of the sacrificial members of the stack structure is performed, and a stacked interconnect structure is formed, as shown in FIG. 27 (S111). Specifically, the sacrificial members 42, 44, 46, and 49 are removed via the slit SH by wet etching using thermal phosphoric acid, etc. At this time, the three-dimensional architecture of the structure from which the sacrificial members 42, 44, 46, and 49 have been removed is maintained by the memory pillars MP and the support pillars HR.

Thereafter, a conductor is embedded in the space from which the sacrificial members 42, 44, 46, and 49 have been removed via the slits SH. In the above-described process, the conductor is formed using, for example, chemical vapor deposition (CVD). Thereafter, the conductor formed in the slits SH is removed by an etch-back process, and the conductor formed in adjacent layers is separated. Thereby, an interconnect layer 22 that functions as a select gate line SGS and a corresponding lift portion LF, a plurality of interconnect layers 23 that respectively function as word lines WL0 to WL7 and corresponding lift portions LF, and an interconnect layer 24 that functions as a select gate line SGD are formed. The interconnect layers 22, 23, and 24 formed in the above-described process may contain a barrier metal. In this case, in the formation of the conductor after the removal of the sacrificial members 42, 44, 46, and 49, tungsten is formed after, for example, a titanium nitride film is formed as a barrier metal.

Subsequently, a member SLT is formed in each slit SH (S112). Specifically, an insulating portion (spacer SP) is formed so as to cover side and bottom surfaces of the slit SH. The spacer SP is partly removed from the bottom of each slit SH, and the interconnect layer 21 is partly exposed at the bottom of each slit SH. Thereafter, a conductor (a contact LI) is formed in each slit SH. The conductor formed outside of the slit SH is removed by, for example, CMP. In an unillustrated region, a plurality of members SHE each of that further divides the interconnect layer 24 of the stacked interconnect structure into a plurality of portions is formed.

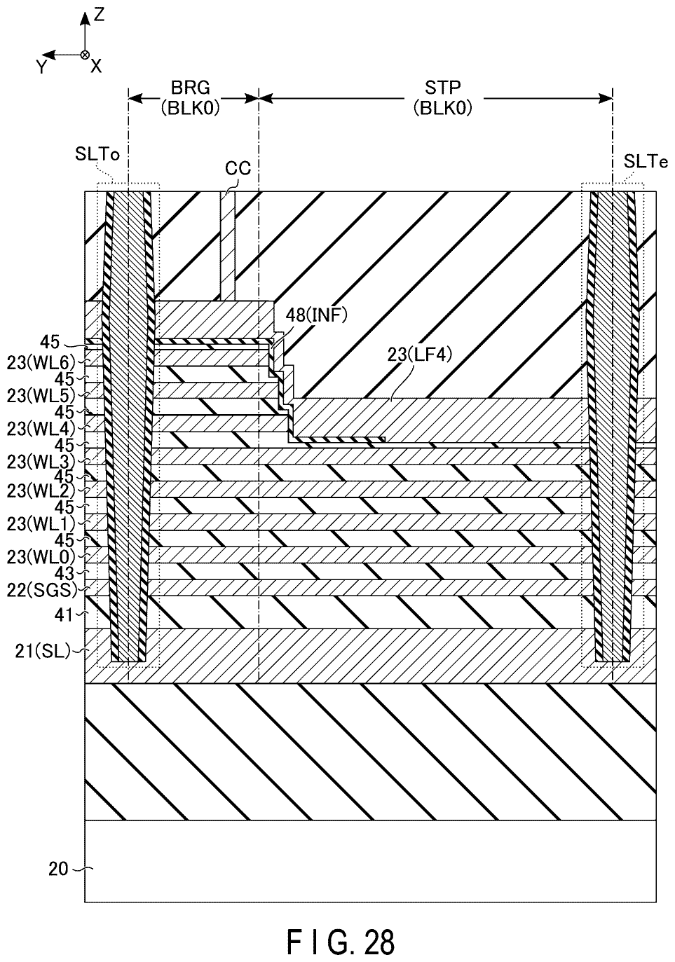

Thereafter, a plurality of contacts CC is formed, as shown in FIG. 28 (S113). Specifically, a mask including openings at positions corresponding to contacts CC is formed by, for example, photolithography. A plurality of holes penetrating the insulator formed above the lift portions LF is formed by anisotropic etching using the mask. At the bottom of each hole, a portion 22-2 of the interconnect layer 22 coupled to the select gate line SGS or a portion 23-2 of the interconnect layer 23 coupled to a corresponding one of the word lines WL0 to WL7 is exposed. Thereafter, the holes are buried by a conductor. Lastly, the conductor formed on the upper surface of the stack structure is removed by, for example, CMP, and thereby surfaces of the contacts CC corresponding to their upper ends are exposed.

Through the above-described manufacturing steps, a stacked interconnect structure in the memory cell array 10 is formed. The above-described manufacturing steps are presented merely as an example, and the configuration is not limited thereto. For example, another step may be inserted between the manufacturing steps, or some of the steps may be omitted or integrated. In addition, the order of the manufacturing steps may be switched wherever possible. For example, the step of forming memory pillars MP may be performed prior to the step of forming trenches TRC.

### 3. Advantageous Effects of Embodiment

According to the present embodiment, it is possible to improve a yield of the semiconductor memory device. This effect will be described in detail below.

A malfunction of a semiconductor memory device may be caused in the case where a contact cannot reach a corresponding interconnect layer of a stacked interconnect structure, resulting in a connection failure between the contact and the corresponding interconnect layer. A malfunction may also be caused in the case where a contact is coupled to an interconnect layer below a corresponding interconnect layer of a stacked interconnect structure, resulting in a short circuit between the two interconnect layers via the contact.

The above-described two cases of malfunctions are ascribable to the requirement for high precision in processing holes for forming contacts. In the case where, in particular, contacts are coupled to interconnect layers provided at different heights, the hole lengths corresponding to the contacts differ. In such a case, it is difficult to suppress both a malfunction caused by a contact not reaching a desired interconnect layer and a malfunction caused by a contact penetrating a desired interconnect layer. This may also cause an increase in the processing cost due to the need to perform processing control with very high precision to form a plurality of contacts with different hole lengths.

In the present embodiment, each of the interconnect layers 22 and 23 of the stacked interconnect structure is coupled to a corresponding contact CC by being lifted to a height substantially identical to the height of the topmost interconnect layer 23 by the corresponding lift portion LF. It is thus possible to process each hole with the same hole length at the time of forming a plurality of holes corresponding to the contacts CC. This eliminates the need to process a plurality of holes with different hole lengths, thus suppressing occurrence of the above-described malfunction caused by coupling of the contact, resulting in improvement in a yield of the semiconductor memory device 3.

Moreover, since the holes corresponding to the contacts CC have the same length, it is possible to simplify the hole processing process. As a result, it is possible to facilitate control of the contact hole processing, thus suppressing an increase in the processing cost of the semiconductor memory device 3.

### 4. Others

Various modifications can be made to the semiconductor memory device according to the present embodiment. A first modification of the present embodiment will be described below, in terms of the matters different from those of the present embodiment.

In the semiconductor memory device according to the first modification, interconnect layers corresponding to a select gate line SGS and word lines WL0 to WL7 are formed in manufacturing steps different from manufacturing steps of the lift portions LF. Specifically, the lift portions LF are formed by burying the trenches TRC with a conductor in place of the sacrificial member 49 at step S106 of manufacturing the semiconductor memory device shown in FIG. 15. The conductor with which the trench TRC is buried contains, for example, tungsten. Thereafter, at S111, replacement of the sacrificial member of the stack structure is performed, and a stacked interconnect structure is formed. At this time, the interconnect layers 22 and 23 are coupled to the corresponding lift portions LF. In the semiconductor memory device according to the first modification, both end portions of the lift portions LF in the Y direction are not necessarily in contact with the members SLT.

With the semiconductor memory device according to the first modification of the present embodiment, it is possible to shorten the step of replacement of the sacrificial member at step S111 of manufacturing the semiconductor memory device shown in FIG. 15. With the semiconductor memory device according to the first modification, since the sacrificial member 49 of the lift portion LF need not be removed at the time of removing the sacrificial members 42, 44, and 46 via the slits SH, the replacement process need not be performed for a complex shape that follows a staircase structure. It is thereby possible to simplify the replacement step S111.

In the present embodiment, a structure has been described in which peripheral circuits corresponding to the row decoder module 15, the sense amplifier module 16, and the like and a memory cell array 10 including the stadium-shaped staircase structure, the memory pillars MP, and the like are formed by being stacked on an identical substrate; however, a structure may be adopted in which the peripheral circuits and the memory cell array are separately formed on individual substrates, and are then bonded. In this case, the memory cell array according to the present embodiment is provided opposite to (upside down relative to) the semiconductor substrate on which the peripheral circuits are formed in the Z direction.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a substrate provided with a plane formed by a first direction and a second direction intersecting each other, the substrate including a first region and a second region aligned in the first direction, the second region including a third region and a fourth region aligned in the second direction;
a plurality of interconnect layers arranged with the substrate in a third direction and including a first interconnect layer, the third direction intersecting each of the first direction and the second direction, the plurality of interconnect layers being spaced from one another in the third direction and each including a bridge portion extending in the first direction in the third region and a terrace portion provided so as not to overlap, in the third direction, an upper interconnect layer in the fourth region;
a first contact extending in the third direction;
a first conductor provided so as to be isolated from the plurality of interconnect layers excluding the first interconnect layer, the first conductor including a first portion contacting the terrace portion of the first interconnect layer in the fourth region, a second portion contacting one end of the first contact in the third region, and a third portion coupling the first portion and the second portion; and
a first memory pillar extending in the third direction in the first region, a portion of the first memory pillar intersecting the first interconnect layer functioning as a first memory cell.

2. The semiconductor memory device according to claim 1, wherein
the terrace portion of each of the plurality of interconnect layers in the fourth region includes a first terrace portion arranged, in the first direction, with the terrace portion of another interconnect layer included in the plurality of interconnect layers, and
the first portion of the first conductor contacts the first terrace portion of the first interconnect layer.

3. The semiconductor memory device according to claim 1, wherein
the plurality of interconnect layers further includes a second interconnect layer provided above the first interconnect layer, and
the third portion of the first conductor includes a portion extending along an end portion in the fourth region of the second interconnect layer in the second direction.

4. The semiconductor memory device according to claim 3, wherein
the terrace portion of each of the plurality of interconnect layers includes a second terrace portion aligned, in the second direction, with the terrace portion of another interconnect layer included in the plurality of interconnect layers, and
the third portion of the first conductor includes a portion extending in the second and third directions along the second terrace portion of the second interconnect layer.

5. The semiconductor memory device according to claim 3, wherein
the second interconnect layer includes, in the fourth region, a first inclined portion inclined in a fourth direction at the end portion in the second direction, the fourth direction being a diagonal direction in a plane formed by the second direction and the third direction, and
the third portion of the first conductor includes the portion extending in the fourth direction along the first inclined portion.

6. The semiconductor memory device according to claim 3, further comprising:
an insulator provided between the first conductor and the second interconnect layer.

7. The semiconductor memory device according to claim 1, wherein
a thickness of each of the first portion and the second portion of the first conductor in the third direction is greater than a thickness of each of the plurality of interconnect layers in the third direction.

8. The semiconductor memory device according to claim 2, wherein
a width of the first portion of the first conductor in the first direction is smaller than a width of the first terrace portion of the first interconnect layer in the first direction.

9. The semiconductor memory device according to claim 1, wherein
the first portion of the first conductor includes a portion overlapping the first interconnect layer as viewed in the first direction,
the second portion of the first conductor includes a portion overlapping a third interconnect layer which is provided at a topmost layer of the plurality of interconnect layers as viewed in the first direction, and
the third portion of the first conductor includes a portion overlapping a fourth interconnect layer which is provided so as to be interposed in the third direction by the first interconnect layer and the third interconnect layer of the plurality of interconnect layers, as viewed in the first direction.

10. The semiconductor memory device according to claim 9, wherein
the third interconnect layer includes a fourth portion and a fifth portion in the third region, and
the fourth portion, the second portion of the first conductor, and the fifth portion are arranged in this order in the first direction.

11. The semiconductor memory device according to claim 10, wherein
the fourth portion and the fifth portion in the third interconnect layer are electrically coupled.

12. The semiconductor memory device according to claim 1, further comprising:
a second contact extending in the third direction; and
a second conductor provided so as to be isolated from the plurality of interconnect layers excluding a fifth interconnect layer included in the plurality of interconnect layers and different from the first interconnect layer, the second conductor including: a sixth portion contacting the terrace portion of the fifth interconnect layer in the fourth region; a seventh portion contacting one end of the second contact in the third region; and an eighth portion coupling the sixth portion and the seventh portion.

13. The semiconductor memory device according to claim 12, wherein
the first conductor and the second conductor are arranged in the first direction.

14. The semiconductor memory device according to claim 12, wherein
the first contact and the second contact are arranged in the first direction in the third region.

15. The semiconductor memory device according to claim 12, wherein
a length of the first contact and a length of the second contact in the third direction are approximately identical.

16. The semiconductor memory device according to claim 2, wherein
terrace portions of the plurality of interconnect layers include:
a first sub terrace portion formed in a staircase shape that descends to one side in the first direction; and
a second sub terrace portion formed in a staircase shape that ascends to the one side in the first direction, and
the first sub terrace portion and the second sub terrace portion are, in the fourth region, arranged in the first direction.

17. The semiconductor memory device according to claim 16, further comprising, in the fourth region:
a second inclined portion in which end portions in the first direction of a plurality of sixth interconnect layers included in the plurality of interconnect layers and continuously stacked on one another are inclined in a fifth direction, the fifth direction being a diagonal direction in a plane formed by the first direction and the third direction, wherein
the second inclined portion is provided so as to be interposed by the first sub terrace portion and the second sub terrace portion in the first direction.

18. The semiconductor memory device according to claim 1, further comprising a second memory pillar, wherein
the substrate further includes a fifth region provided so as to interpose the second region together with the first region in the first direction, and
the second memory pillar extends in the third direction in the fifth region, and a portion intersecting the first interconnect layer functions as a second memory cell.

19. The semiconductor memory device according to claim 1, further comprising:
a first insulating member and a second insulating member extending in the first direction and interposing the first region and the second region in the second direction.

20. The semiconductor memory device according to claim 19, wherein
each of the interconnect layers is, in the second direction, in contact with the first insulating member on a side of the third region, and in contact with the second insulating member on a side of the fourth region,
the first portion of the first conductor contacts the second insulating member in the second direction, and
the second portion of the first conductor contacts the first insulating member in the second direction.
